(19) United States
(12) Patent Application Publication
(10) Pub. No.: US 2024/0168211 A1
(43) Pub. Date: May 23, 2024

(54) PHASE DIFFERENCE FILM

(71) Applicant: OSAKA GAS CHEMICALS CO., LTD., Osaka (JP)

(72) Inventors: Shogo SUGA, Osaka (JP); Yoshiya OTA, Osaka (JP); Katsuhide OKIMI, Osaka (JP); Yasuhiro SUDA, Osaka (JP)

(21) Appl. No.: 18/280,654

(22) PCT Filed: Mar. 15, 2022
(86) PCT No.: PCT/JP2022/011597

§ 371 Date: Sep. 6, 2023

(30) Foreign Application Priority Data
Mar. 16, 2021 (JP) 2021-042964

(51) Int. Cl. G02B 5/30; B32B 7/023; B32B 27/34; B32B 27/36; H10K 59/80

(52) U.S. Cl. CPC G02B 5/3083; B32B 7/023; B32B 27/34; B32B 27/36; G02B 5/305; H10K 59/879; B32B 2262/103; B32B 2305/55; B32B 2307/302; B32B 2307/412

(57) ABSTRACT

A phase difference film comprising one layer or multiple layers, wherein at least one layer thereof comprises a composition containing a polyester resin having arylated fluorene in a side chain, a relationship between phase differences Ro(450) and Ro(550) in an in-plane direction of the layer comprising the polyester resin is Ro(450)/Ro(550)≥1.22, and the layer(s) is drawn.

### TECHNICAL FIELD

The present invention relates to a phase difference film that exhibits negative intrinsic birefringence, has a large property of exerting a phase difference, and is excellent in coatability, and as such can be suitably used as a thin-film negative A plate, positive B plate, or positive C plate in a ½λ plate, a ¼λ phase difference film, a viewing angle compensation film, an antireflection film, or the like, and a polarizing plate and an image display apparatus comprising the same.

### BACKGROUND ART

In a display apparatus such as a liquid crystal display (LCD), a phase difference film is used for optical compensation that prevents reduction in contrast or color change caused by a viewing angle. In an organic EL display apparatus, unlike an LCD display apparatus, a phase difference film is used for suppressing reduction in contrast caused by outside light reflection. Since such a phase difference film requires optimally designing a three-dimensional refractive index depending on the purposes of these display apparatuses, a material having positive intrinsic birefringence and a material having negative intrinsic birefringence are used in combination.

As the material having positive intrinsic birefringence generally has wide material selectivity, a material such as triacetylcellulose, polycarbonate, or polycycloolefin is mainly used.

On the other hand, as a small number of materials can be selected in the first place as the material having negative intrinsic birefringence, polymethyl methacrylate-based polymers, polystyrene-based polymers, and the like are known (Patent Literatures 1 and 2). However, all of these polymers disadvantageously have insufficient heat resistance and are difficult to handle because the polymers are fragile and tear easily. Among them, polymethyl methacrylate-based polymers have a low property of exerting a phase difference, and phase difference films are therefore difficult to obtain therefrom. On the other hand, polystyrene-based polymers are difficult to handle as a single layer, and their multilayer films with polycarbonate-based polymers having strong rigidity have therefore been proposed (Patent Literature 3). However, such multilayer films have a problem associated with toughness required for molding and are thus insufficient for a practical level.

### CITATION LIST

### Patent Literature

### Patent Literature 1: Japanese Patent Laid-Open No. 2003-043253

### Patent Literature 2: Japanese Patent Laid-Open No. 2007-24940

### Patent Literature 3: Japanese Patent Laid-Open No. 2014-149508

### Patent Literature 4: Japanese Patent Laid-Open No. 11-52131

### SUMMARY OF INVENTION

### Technical Problem

A polyester resin film having a fluorene ring in a side chain is possible as a phase difference film that has negative intrinsic birefringence and is excellent in toughness. However, the polyester resin film having a fluorene ring in a side chain has an insufficient property of exerting a phase difference and cannot therefore produce a thin phase difference film.

A phase difference film having a liquid crystal layer has been put to practical use as a thin phase difference film (Patent Literature 4). The liquid crystal layer can exert a phase difference by applying a liquid crystal compound onto a base material film and orienting them. However, the phase difference film having the liquid crystal layer requires many complicated steps such as an orientation treatment step and a transfer step of the liquid crystal layer to a polarizing plate for production thereof. Furthermore, these complicated steps must employ an expensive liquid crystal compound and in addition, generally have a problem associated with yields. Thus, a production cost is very high for such a phase difference film which is scheduled for large-scale production. Hence, there is a demand for a thin phase difference film that is more inexpensive and also contributes to reduction in production cost.

An object of the present invention is to provide a more inexpensive and thin phase difference film that has a high property of exerting a phase difference and is excellent in handleability, and a method for producing the same, a polarizing plate comprising the phase difference film, an image display apparatus comprising the polarizing plate, and an information processing apparatus comprising the image display apparatus.

### Solution to Problem

The present inventors have conducted diligent studies to attain the object and consequently completed the present invention by finding that a polyester resin containing an arylated fluorene ring in a side chain exhibits large negative intrinsic birefringence, and finding that a thin and easy-to-handle phase difference film can be inexpensively formed by film formation and drawing.

Specifically, the present invention is as follows.

[1]

A phase difference film comprising

one layer or multiple layers, wherein

at least one layer thereof comprises a composition containing a polyester resin having arylated fluorene in a side chain,

a relationship between phase differences Ro(450) and Ro(550) in an in-plane direction of the layer comprising the polyester resin is Ro(450)/Ro(550)≥1.22, and the layer(s) is drawn.

[2]

The phase difference film according to [1], wherein

the composition exhibits negative intrinsic birefringence.

[3]

The phase difference film according to [1] or [2], wherein

the polyester resin comprises, as monomers, a dicarboxylic acid component represented by the following general formula (1) and at least one diol component selected from the group consisting of a diol component (A) represented by the following general formula (2), a diol component (B) represented by the following general formula (3), and a diol component (C) represented by the following general formula (4), and

in the contained polyester resin, k is 1 or more in at least a portion or the whole of the dicarboxylic acid component represented by the following general formula (1):

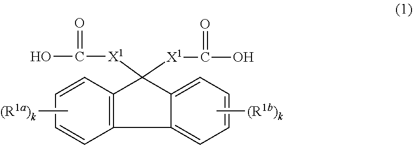

wherein R^{1a} and R^{1b} each independently represent a phenyl group or a naphthyl group, each k independently represents an integer of 0 to 4, and each X¹ independently represents a C₁₋₈ alkylene group,

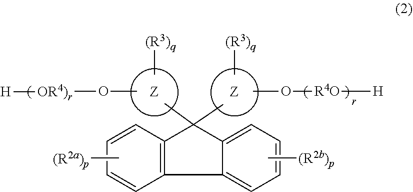

wherein each Z independently represents a phenylene group or a naphthylene group, R^{2a} and R^{2b} each independently represent a substituent inert to reaction, each p independently represents an integer of 0 to 4, each R³ independently represents an alkyl group, an alkoxy group, a cycloalkyloxy group, an aryloxy group, an aralkyloxy group, an aryl group, a cycloalkyl group, an aralkyl group, a halogen atom, a nitro group, or a cyano group, each q independently represents an integer of 0 to 2, each R⁴ independently represents a C₂₋₆ alkylene group, and each r independently represents an integer of 1 or larger,

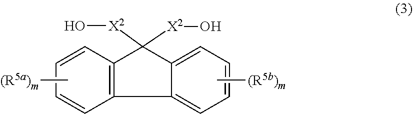

wherein R^{5a} and R^{5b} each independently represent a substituent inert to reaction, each m independently represents an integer of 0 to 4, and each X² independently represents a C₁₋₈ alkylene group,

HO—X³—OH (4)

wherein X³ represents a C₂₋₈ alkylene group.
[4]

The phase difference film according to [3], wherein

the polyester resin comprises a polyester resin comprising, as monomers, a dicarboxylic acid component of the general formula (1) wherein each of R^{1a} and R^{1b} is a 2-naphthyl group, k is 1, and X¹ is an ethylene group, and at least one diol component selected from the group consisting of a diol component (A) of the general formula (2) wherein Z is a phenylene group, each of p and q is 0, R⁴ is an ethylene group, and r is 1, and a diol component (C) of the general formula (4) wherein X³ is an ethylene group.

[5]

The phase difference film according to any one of [1] to [4], wherein

the composition containing the polyester resin having the arylated fluorene in a side chain is a polymer alloy comprising the polyester resin having the arylated fluorene in a side chain, and a polycarbonate resin.

[6]

The phase difference film according to any one of [1] to [5], wherein

the phase difference film is a multilayer film comprising a layer comprising the polyester resin, and a resin layer having positive intrinsic birefringence.

[7]

The phase difference film according to [6], wherein

the resin layer having positive intrinsic birefringence comprises a polyamide-based resin.

[8]

The phase difference film according to any one of [1] to [7], wherein

the phase difference film is a ¼λ phase difference film.

[9]

The phase difference film according to any one of [1] to [8], wherein

when an in-plane direction of the phase difference film that exhibits a maximum refractive index is defined as an X axis, an in-plane direction of the phase difference film that is orthogonal to the X axis is defined as a Y axis, and a thickness direction of the phase difference film is defined as a Z axis,

a refractive index (nx) of the X axis, a refractive index (ny) of the Y axis, and a refractive index (nz) of the Z axis satisfy any of relationships represented by the following expressions (5) to (7):

nx=nz>ny (5)

nz>nx>ny (6)

nx=ny<nz (7)

[10]

The phase difference film according to any one of [1] to [9], wherein

the phase difference film is a multilayer film comprising a liquid crystal phase difference layer made of an oriented liquid crystal material.

[11]

The phase difference film according to any one of [1] to [10], wherein

the phase difference film is a multilayer film having a transparent conductive layer on one side or both sides.

[12]

The phase difference film according to [11], wherein

the transparent conductive layer comprises a plurality of metal thin wires.

[13]

The phase difference film according to [12], wherein

the metal thin wires are made of silver, copper, or an alloy comprising at least one of silver and copper.

[14]

The phase difference film according to any one of [11] to [13], wherein

the transparent conductive layer comprises at least one of indium tin oxide (ITO), antimony-doped tin oxide (ATO), a conductive polymer, and a carbon-based material.

[15]

A method for producing the phase difference film according to any one of [1] to [14], comprising

a drawing step of drawing a film comprising one layer or multiple layers comprising a composition containing a polyester resin having arylated fluorene in a side chain in a direction of 45°±15° with respect to a width direction.

[16]

A method for producing a film comprising multiple layers as the phase difference film according to any one of [1] to [14], comprising the steps of:

performing multilayer film formation of the film comprising multiple layers by a coextrusion molding method, a coating molding method, an extrusion lamination molding method, or a lamination method; and

then drawing the film.

[17]

A polarizing plate comprising

the phase difference film according to any one of [1] to [14].

[18]

The polarizing plate according to [17], further comprising

a ¼λ phase difference film on the visible side of the phase difference film.

[19]

The polarizing plate according to [18], wherein

the polarizing plate has a surface treatment layer on the ¼λ phase difference film on the visible side.

[20]

The polarizing plate according to [19], wherein

the surface treatment layer has any one or more of hard coat, antiglare, antireflection, low-reflection, antifouling, and anti-fingerprint effects.

[21]

An image display apparatus comprising

the polarizing plate according to any one of [17] to [20].

[22]

The image display apparatus according to [21], further comprising

a touch sensor.

[23]

The image display apparatus according to [22], wherein

the touch sensor has an on-cell system or an in-cell system.

[24]

The image display apparatus according to [22] or [23], wherein

the touch sensor is a capacitive touch sensor having at least one conductive film.

[25]

The image display apparatus according to [24], wherein

a base material of the conductive film is a polyester resin, a cycloolefin resin, a polycarbonate resin, or a polyimide resin.

[26]

The image display apparatus according to [24] or [25], wherein

the conductive film comprises a plurality of metal thin wires.

[27]

The image display apparatus according to [26], wherein

the metal thin wires are made of silver, copper, or an alloy comprising at least one of silver and copper.

[28]

The image display apparatus according to any one of [24] to [27], wherein

the conductive film comprises at least one of indium tin oxide (ITO), antimony-doped tin oxide (ATO), a conductive polymer, and a carbon-based material.

[29]

The image display apparatus according to any one of [21] to [28], wherein

the image display apparatus has a changeable shape.

[30]

The image display apparatus according to any one of [21] to [29], wherein

the image display apparatus is an in-car image display apparatus.

[31]

An information processing apparatus comprising

the image display apparatus according to any one of [21] to [30].

### Advantageous Effects of Invention

The present invention can provide more inexpensive and thin phase difference film that has a high property of exerting a phase difference and is excellent in handleability, and a method for producing the same, a polarizing plate comprising the phase difference film, an image display apparatus comprising the polarizing plate, and an information processing apparatus comprising the image display apparatus.

A film obtained by the film formation of a composition containing a polyester resin having the arylated fluorene ring described above in a side chain, when uniaxially drawn, exhibits a negative phase difference (negative intrinsic refractive index) because the plane of the arylated fluorene ring in a side chain is orthogonal to the backbone and therefore, a refractive index in a direction orthogonal to the direction of drawing is higher than that in the direction of drawing. Furthermore, such a film is excellent in property of exerting a phase difference because a refractive index differs largely between the arylated fluorene ring and the backbone. As for other effects, the polyester resin of the present invention is excellent in heat resistance and toughness and is easy to handle because of easy film formation, though a general polymer that exhibits negative intrinsic birefringence is often brittle. Hence, the phase difference film comprising the composition can be suitably used as a thin phase difference film effective for a viewing angle compensation as a negative A plate, a positive B plate, and a positive C plate.

The phase difference film of the present invention exhibits a positive phase difference and can also be suitably used as a ¼λ phase difference film for a circularly polarizing plate having broadband antireflection performance by lamination with a resin film having smaller wavelength dispersion than that of the phase difference film of the present invention. Furthermore, the phase difference film of the present invention can be provided more inexpensively than a liquid crystal application-type ¼ phase difference film because of easy film formation.

### BRIEF DESCRIPTION OF DRAWINGS

FIG. 1 is a cross-sectional view schematically illustrating a ¼λ phase difference film according to one embodiment of the present invention.

FIG. 2A is a cross-sectional view schematically illustrating a polarizing plate according to one embodiment of the present invention.

FIG. 2B is a cross-sectional view schematically illustrating a polarizing plate according to another embodiment of the present invention.

FIG. 3A is a cross-sectional view schematically illustrating an image display apparatus (OLED) according to one embodiment of the present invention.

FIG. 3B is a cross-sectional view schematically illustrating an image display apparatus (LCD) according to one embodiment of the present invention.

FIG. 4 is a cross-sectional view schematically illustrating a rollable display according to one embodiment of the present invention.

FIG. 5 is a perspective view schematically illustrating an information processing apparatus according to one embodiment of the present invention.

FIG. 6 is a perspective view schematically illustrating a foldable smartphone according to one embodiment of the present invention.

FIG. 7 is a perspective view schematically illustrating a rollable smartphone according to one embodiment of the present invention.

### DESCRIPTION OF EMBODIMENTS

Hereinafter, the mode for carrying out the present invention (hereinafter, referred to as the “present embodiment”) will be described in detail. However, the present invention is not limited thereby, and various changes or modifications can be made in the present invention without departing from the spirit of the present invention.

### Phase Difference Film

The phase difference film of the present embodiment comprises a composition containing a polyester resin having arylated fluorene in a side chain, wherein a relationship between phase differences Ro(450) and Ro(550) in an in-plane direction of the layer comprising the polyester resin is Ro(450)/Ro(550)≥1.22, and the layer(s) is drawn. By use of such a polyester resin having arylated fluorene in a side chain, the orientation direction of the arylated fluorene ring is orthogonal to the backbone direction of the polyester resin. The resulting film, when drawn, easily exerts a phase difference and is considered to exert an excellent property of exerting a phase difference.

The polyester resin of the present embodiment has a high refractive index in a direction orthogonal to the backbone direction of the polyester resin due to the influence of the arylated fluorene ring, and tends to exhibit negative intrinsic birefringence. In this context, the backbone direction of the polyester resin is a direction of drawing when a polymer film is drawn. The direction orthogonal thereto is a direction orthogonal to the direction of drawing.

In one aspect, the phase difference Ro(450 nm) in the in-plane direction of the layer comprising the polyester resin having arylated fluorene in a side chain is preferably 1500 to 8000 nm, more preferably 2000 to 7500 nm, further preferably 2500 to 7000 nm, still further preferably 3000 to 6500 nm.

The phase difference Ro(550 nm) in the in-plane direction of the layer comprising the polyester resin having arylated fluorene in a side chain is preferably 1000 to 6000 nm, more preferably 1500 to 5500 nm, further preferably 2000 to 5000 nm, still further preferably 2500 to 5000 nm.

Ro(450 nm)/Ro(550 nm) of the layer comprising the polyester resin having arylated fluorene in a side chain is preferably 1.15 to 2.00, more preferably 1.20 to 2.00, further preferably 1.22 to 2.00, still further preferably 1.25 to 2.00.

The phase difference Rₜₕ(550 nm) in the thickness direction of the layer comprising the polyester resin having arylated fluorene in a side chain is preferably −3000 to −500 nm, more preferably −2750 to −750 nm, further preferably −2500 to −1000 nm.

In one aspect, Ro(450 nm) of the whole phase difference film is preferably 55 to 160 nm, more preferably 70 to 145 nm, further preferably 85 to 130 nm.

Ro(550 nm) of the whole phase difference film is preferably 80 to 180 nm, more preferably 100 to 165 nm, further preferably 120 to 150 nm.

Ro(450 nm)/Ro(550 nm) of the whole phase difference film is preferably 0.50 to 0.90, more preferably 0.55 to 0.92, further preferably 0.60 to 0.94, still further preferably 0.65 to 0.96.

### Polyester Resin Composition

The polyester resin composition constituting the phase difference film of the present embodiment comprises the predetermined polyester resin and may optionally comprise other components that are routinely used to constitute phase difference films, such as other additives mentioned later.

### Polyester Resin

The polyester resin of the present embodiment has arylated fluorene in a side chain and can be obtained by, for example, the polymerization of a dicarboxylic acid component having arylated fluorene and an arbitrary diol component; the polymerization of an arbitrary dicarboxylic acid component and a diol component having arylated fluorene; or the polymerization of a dicarboxylic acid component having arylated fluorene and a diol component having arylated fluorene.

In the present embodiment, the “arylation” refers to the introduction of aromatic hydrocarbon or a derivative thereof through a C—C single bond. The aromatic hydrocarbon may be, for example, a polycyclic aromatic hydrocarbon group such as a naphthyl group.

As long as at least any one of the dicarboxylic acid component and the diol component comprises a compound having arylated fluorene, one each of the components may be used singly, or two or more each of the components may be used in combination.

The glass transition temperature of the polyester resin of the present embodiment is preferably 90 to 190° C., more preferably 100 to 180° C., further preferably 110 to 170° C. When the glass transition temperature is 90° C. or higher, the heat resistance of the polyester resin tends to be more improved. When the glass transition temperature is 190° C. or lower, the drawability of the polyester resin tends to be more improved. The glass transition temperature can be measured by a method described in Examples mentioned later.

The weight-average molecular weight of the polyester resin of the present embodiment is preferably 30000 to 200000, more preferably 35000 to 150000, further preferably 40000 to 100000. When the weight-average molecular weight falls within the range described above, the polyester resin has a long molecular chain, mechanical characteristics such as elongation at break and flexibility tend to be more improved, and drawability tends to be more improved. In the present embodiment, the weight-average molecular weight can be measured by gel permeation chromatography (GPC) based on polystyrene. More specifically, the weight-average molecular weight can be measured by, for example, a method described in Examples mentioned later.

Hereinafter, each component constituting the polyester resin will be described in detail.

### Dicarboxylic Acid Component

Examples of the dicarboxylic acid component which is a monomer constituting the polyester resin used in the present embodiment include, but are not particularly limited to, a compound represented by the following general formula (1):

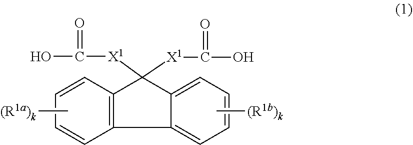

wherein R^{1a} and R^{1b} each independently represent a phenyl group or a naphthyl group, each k independently represents an integer of 0 to 4, and each X¹ independently represents a C₁₋₈ alkylene group.

In the general formula (1), the substitution position on the fluorene ring of the phenyl group or the naphthyl group represented by the group R^{1a} or R^{1b} is not particularly limited and is the 2-position or/and the 7-position in view of an industrial synthesis method of the monomer. The phenyl group has a smaller property of exerting a phase difference than that of the naphthyl group, and the naphthyl group is preferred from the viewpoint of a property of exerting a phase difference. The naphthyl group may be a 1-naphthyl group or may be a 2-naphthyl group. The 2-naphthyl group has a lager property of exerting a phase difference and is thus preferred from the viewpoint of a property of exerting a phase difference.

A mixture of a phenyl group-substituted form in which each of the groups R^{1a} and R^{1b} is a phenyl group and a naphthyl group-substituted form in which each of the groups R^{1a} and R^{1b} is a naphthyl group, which is a dicarboxylic acid component having arylated fluorene, may be used as a starting material monomer in polymerization for the polyester resin, or each monomer may be polymerized alone, and the resulting polyester resins may be mixed. Alternatively, a dicarboxylic acid component in which one of the groups R^{1a} and R^{1b} is a phenyl group, and the other group is a naphthyl group may be used in polymerization for the polyester resin. Any of these methods are effective for the purpose of adjusting a property of exerting a phase difference.

The number k of substitutions of the groups R^{1a} and R^{1b} may be 0, i.e., no substitution. k for both the groups is 1 or larger from the viewpoint of a property of exerting a phase difference, and fluorene is preferably substituted at both ends by aryl groups. From such a viewpoint, the number k of substitutions preferably represents an integer of 1 to 3 and more preferably represents 1. In a dicarboxylic acid component having arylated fluorene, at least one of the two k moieties is 1 or larger, and both the two k moieties are preferably 1.

A mixture of a fluorenedicarboxylic acid component in an unsubstituted form having no aryl group and a fluorenedicarboxylic acid component in a substituted form having an aryl group, which is a dicarboxylic acid component, may be used as a starting material monomer in polymerization for the polyester resin, or each monomer may be polymerized alone, and the resulting polyester resins may be mixed. Any of these methods are effective for the purpose of adjusting a property of exerting a phase difference.

In the general formula (1), examples of the C₁₋₈ alkylene group represented by X¹ can include linear or branched alkylene groups, for example, C₁₋₈ alkylene groups such as a methylene group, an ethylene group, a trimethylene group, a propylene group, a 2-ethylethylene group, and a 2-methylpropane-1,3-diyl group. Among them, the alkylene group is preferably a linear or branched C₁₋₆ alkylene group (e.g., a C₁₋₄ alkylene group such as a methylene group, an ethylene group, a trimethylene group, a propylene group, or a 2-methylpropane-1,3-diyl group).

Typical examples of the compound represented by the general formula (1) include, but are not particularly limited to, 9,9-bis(2-carboxyethyl)fluorene, 9,9-bis(2-carboxypropyl) fluorene, 9,9-bis (carboxy-C₄₋₆ alkyl)fluorene, 9,9-bis(2-carboxyethyl)2,7-diphenylfluorene, 9,9-bis(2-carboxypropyl)2,7-diphenylfluorene, 9,9-bis(carboxy-C₄₋₆alkyl)2,7-diphenylfluorene, 9,9-bis(2-carboxyethyl)2,7-di(2-naphthyl)fluorene, 9,9-bis(2-carboxypropyl)2,7-di(2-naphthyl)fluorene, 9,9-bis (carboxy-C₄₋₆ alkyl)2,7-di(2-naphthyl)fluorene, 9,9-bis(2-carboxyethyl)2,7-di(1-naphthyl)fluorene, 9,9-bis(2-carboxypropyl)2,7-di(1-naphthyl)fluorene, and 9,9-bis(carboxy-C₄₋₆ alkyl)2,7-di(1-naphthyl)fluorene. These fluorenedicarboxylic acid components may each be used singly, or two or more thereof may be combined.

Among them, the fluorenedicarboxylic acid component is preferably 9,9-bis(2-carboxyethyl)2,7-di(2-naphthyl)fluorene of the general formula (1) wherein each of R^{1a} and R^{1b} is a 2-naphthyl group, k is 1, and X¹ is an ethylene group. By use of such a dicarboxylic acid component, a property of exerting a phase difference tends to be more improved.

The dicarboxylic acid component is not only free carboxylic acid but includes ester-forming derivatives of the dicarboxylic acid, for example, ester [e.g., alkyl ester [e.g., lower alkyl ester (e.g., C₁₋₄ alkyl ester, particularly, C₁₋₂ alkyl ester) such as methyl ester or ethyl ester]], acid halide (e.g., acid chloride), and acid anhydride. These dicarboxylic acid components can each be used singly, or two or more thereof can be used in combination.

In the polyester resin used in the present embodiment, a dicarboxylic acid component having no fluorene ring may be used in combination with the dicarboxylic acid component represented by the general formula (1).

The ratio of a dicarboxylic acid component represented by the general formula (1) wherein k is 1 or larger among dicarboxylic acid components to be introduced to the polyester resin is preferably 80 to 100% by mol, more preferably 90 to 100% by mol, further preferably 95 to 100% by mol, particularly preferably 100% by mol. When the ratio of the dicarboxylic acid component represented by the general formula (1) wherein k is 1 or larger, i.e., a dicarboxylic acid component having an arylated fluorene ring, falls within the range described above, an excellent property of exerting a phase difference tends to be exerted.

### Method for Producing Dicarboxylic Acid Component

A method for producing 9,9-bis(2-methoxycarbonylethyl)2,7-di(2-naphthyl)fluorene (DNFDP-m) represented by the following general formula (8) will be described as a representative example of alkyl ester of the dicarboxylic acid component represented by the general formula (1):

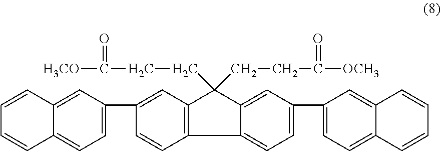

A reaction scheme (9) given below shows a synthesis route of DNFDP-m. There are a plurality of synthesis routes, and the present invention is not limited thereby.

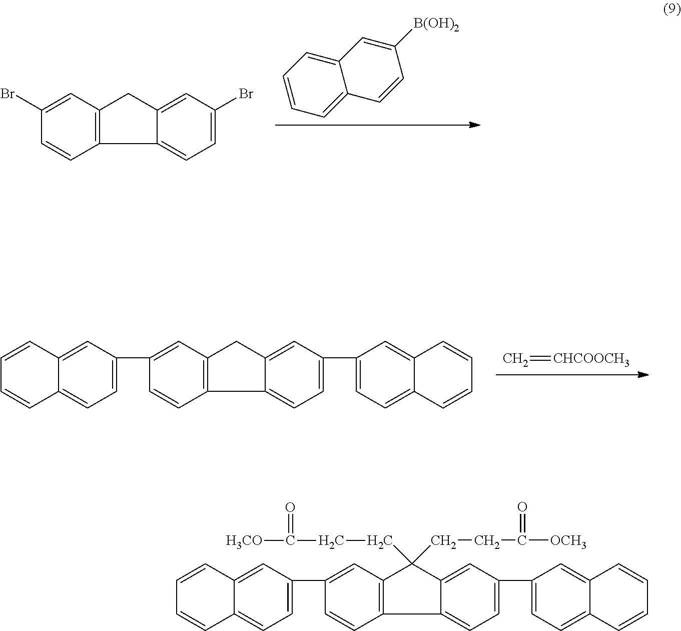

In the reaction scheme (9), 2,7-dibromofluorene is reacted (Suzuki-Miyaura cross coupling) as a starting material with 2-naphthylboronic acid to form 2,7-di(2-naphthyl)fluorene (DNF). Further, DNFDP-m is obtained through the addition reaction (Michael addition) of DNF with methyl acrylate.

The Suzuki-Miyaura cross coupling at the first stage usually involves reacting a brominated aromatic compound with an aromatic compound having a boronic acid group using a palladium catalyst in the presence of a base. Examples of the base include, but are not particularly limited to, sodium carbonate, potassium carbonate, sodium bicarbonate, sodium hydroxide, potassium hydroxide, barium hydroxide, potassium fluoride, tripotassium phosphate, and potassium acetate. Among them, usually, alkali metal carbonate such as potassium carbonate is often used. The ratio of the base used is, for example, on the order of 0.1 to 50 mol, preferably 1 to 25 mol, per mol of 2,7-dibromofluorene. In the reaction, potassium carbonate can be used.

Examples of the palladium catalyst include, but are not particularly limited to, tetrakis(triphenylphosphine)palladium(0), bis(tri-t-butylphosphine)palladium(0), [1,2-bis(diphenylphosphino)ethane]palladium(II) dichloride, [1,3-bis(diphenylphosphino)propane]palladium(II) dichloride, [1,1′-bis(diphenylphosphino)ferrocene]palladium(II) dichloride, bis(triphenylphosphine)palladium(II) dichloride, and bis(tri-o-tolylphosphine)palladium(II) dichloride. Among these catalysts, usually, tetrakis(triphenylphosphine)palladium(0) is often used. The ratio of the catalyst is, for example, on the order of 0.01 to 0.1 mol, preferably 0.03 to 0.07 mol, in terms of a metal per mol of 2,7-dibromofluorene. In the reaction, tetrakis(triphenylphosphine)palladium(0) can be used.

The coupling reaction may be performed in the presence of a solvent. In the reaction, toluene can be used as the solvent.

The reaction temperature of the coupling reaction is, for example, 50 to 200° C., preferably 60 to 100° C. In the reaction, the reaction temperature is 70 to 80° C.

After the completion of the reaction, the reaction mixture may be separated or purified, if necessary, by a common separation or purification method. In the reaction, the reaction mixture can be washed with water and then purified by crystallization.

The Michael addition reaction at the second stage is a reaction through which carbon at the 9-position of fluorene is added to the β-position of unsaturated carboxylic acid ester in the presence of a basic catalyst. Methyl acrylate is added dropwise together with a catalyst to a solution containing DNF obtained through the reaction at the first stage, dissolved in a solvent, and the reaction is performed at 50 to 60° C.

The basic catalyst is not particularly limited as long as a fluorene anion can be formed. A common inorganic base or organic base can be used. Examples of the inorganic base include metal hydroxide (e.g., alkali metal hydroxide such as lithium hydroxide, sodium hydroxide, and potassium hydroxide, and alkaline earth metal hydroxide such as calcium hydroxide and barium hydroxide).

Examples of the organic base can include metal alkoxide (alkali metal alkoxide such as sodium methoxide and sodium ethoxide) and quaternary ammonium hydroxide (e.g., tetraalkylammonium hydroxide such as tetramethylammonium hydroxide, tetraethylammonium hydroxide, and tetra-n-butylammonium hydroxide, and trimethylbenzylammonium hydroxide). The trimethylbenzylammonium hydroxide may be obtained, for example, as trade name “Triton B” (40% solution of trimethylbenzylammonium hydroxide in methanol) from Tokyo Chemical Industry Co., Ltd. Triton B can be used in the synthesis of the DNFDP-m of the present embodiment.

The Michael addition reaction may be performed in the presence of a solvent. The solvent is not particularly limited as long as the solvent is nonreactive with the catalyst and is capable of dissolving a fluorene compound. A wide range of solvents can be used. Methyl isobutyl ketone can be used as the solvent in the synthesis of the DNFDP-m of the present embodiment.

After the completion of the reaction, the reaction mixture may be separated or purified, if necessary, by a common separation or purification method. In the reaction, the reaction mixture can be washed with water and then purified by crystallization.

### Diol Component

The diol component which is a monomer constituting the polyester resin used in the present embodiment is not particularly limited. For example, at least one diol component selected from the group consisting of a diol component (A) represented by the general formula (2) given below, a diol component (B) represented by the general formula (3) given below, and a diol component (C) represented by the general formula (4) given below is preferably used. Hereinafter, each diol component will be described in detail.

### Diol Component (A)

The diol component (A) which is a monomer that may constitute the polyester resin used in the present embodiment can be represented by the following general formula (2):

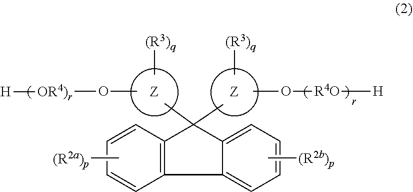

wherein each Z independently represents a phenylene group or a naphthylene group, R^{2a} and R^{2b} each independently represent a substituent inert to reaction, each p independently represents an integer of 0 to 4, each R³ independently represents an alkyl group, an alkoxy group, a cycloalkyloxy group, an aryloxy group, an aralkyloxy group, an aryl group, a cycloalkyl group, an aralkyl group, a halogen atom, a nitro group, or a cyano group, each q independently represents an integer of 0 to 2, each R⁴ independently represents a C₂₋₆ alkylene group, and each r independently represents an integer of 1 or larger.

In the general formula (2), examples of the groups R^{2a} and R^{2b} include, but are not particularly limited to, nonreactive substituents such as a cyano group, halogen atoms (a fluorine atom, a chlorine atom, a bromine atom, etc.), and hydrocarbon groups [e.g., alkyl groups and aryl groups (C₆₋₁₀ aryl groups such as a phenyl group)]. Each of the groups may be a halogen atom, a cyano group, or an alkyl group (particularly, an alkyl group). Examples of the alkyl group can include C₁₋₁₂ alkyl groups (e.g., C₁₋₈ alkyl groups, particularly, C₁₋₄ alkyl groups such as a methyl group) such as a methyl group, an ethyl group, a propyl group, an isopropyl group, a butyl group, and a t-butyl group. The types of the groups R^{2a} and R^{2b} may be the same as or different from each other. The substitution positions of the groups R^{2a} and R^{2b} may be, for example, the 2-position, 7-position, or the 2- and 7-positions of fluorene. The number p of substitutions may be on the order of 0 to 4 (e.g., 0 to 2) and is preferably 0 or 1, particularly, 0.

In the present embodiment, the phrase “inert to reaction” means being inert to polymerization reaction for the polyester resin.

In the general formula (2), examples of the substituent R³ can include, but are not particularly limited to: hydrocarbon groups such as alkyl groups (e.g., C₁₋₆ alkyl groups such as a methyl group, an ethyl group, a propyl group, an isopropyl group, a butyl group, and a t-butyl group), cycloalkyl groups (e.g., C₅₋₈ cycloalkyl groups such as a cyclohexyl group), aryl groups (e.g., C₆₋₁₀ aryl groups such as a phenyl group, a tolyl group, a xylyl group, and a naphthyl group), and aralkyl groups (e.g., C₆₋₁₀ aryl-C₁₋₄ alkyl groups such as a benzyl group and a phenethyl group); alkoxy groups (e.g., C₁₋₆ alkoxy groups such as a methoxy group and an ethoxy group), cycloalkyloxy groups (e.g., C₅₋₈ cycloalkyloxy groups such as a cyclohexyloxy group), aryloxy groups (e.g., C₆₋₁₀ aryloxy groups such as a phenoxy group), and aralkyloxy groups (e.g., C₆₋₁₀ aryl-C₁₋₄ alkyloxy groups such as a benzyloxy group); halogen atoms (e.g., a fluorine atom, a chlorine atom, a bromine atom, and an iodine atom); a nitro group; and a cyano group.

Preferred examples of the group R³ include alkyl groups (C₁₋₆ alkyl groups, preferably C₁₋₄ alkyl groups, particularly, a methyl group), alkoxy groups (C₁₋₄ alkoxy groups, etc.), cycloalkyl groups (C₅₋₈ cycloalkyl groups), and aryl groups (C₆₋₁₂ aryl groups such as a phenyl group).

The number q of substitutions may be, for example, 0 to 4 (e.g., 0 to 3) and is preferably 0 to 2 (e.g., 0 or 1).

In the general formula (2), examples of the C₂₋₆ alkylene group represented by the group R⁴ include, but are not particularly limited to, linear or branched C₂₋₆ alkylene groups such as an ethylene group, a propylene group (1,2-propanediyl group), a trimethylene group, a 1,2-butanediyl group, and a tetramethylene group, preferably C₂₋₄ alkylene groups, further preferably C₂₋₃ alkylene groups.

The number (number of moles of addition) r of oxyalkylene groups (OR⁴) can be 1 or larger and may be, for example, 1 to 12 (e.g., 1 to 8), preferably 1 to 5 (e.g., 1 to 4), further preferably 1 to 3 (e.g., 1 or 2), particularly, 1.

Representative examples of the diol component (A) include 9,9-bis(hydroxy(poly)alkoxyphenyl)fluorenes and 9,9-bis(hydroxy(poly)alkoxynaphthyl)fluorenes.

Examples of the 9,9-bis(hydroxy(poly)alkoxyphenyl)fluorenes include: (i) 9,9-bis(hydroxy-C₂₋₄ alkoxyphenyl)fluorene such as 9,9-bis[4-(2-hydroxyethoxy)phenyl]fluorene and 9,9-bis[4-(2-hydroxypropoxy)phenyl] fluorene; (ii) 9,9-bis (hydroxy-C₂₋₄ alkoxy-mono- or di-C₁₋₄ alkylphenyl)fluorene such as 9,9-bis[4-(2-hydroxyethoxy)-3-methylphenyl]fluorene, 9,9-bis(4-(2-hydroxyethoxy)-3-isopropylphenyl)fluorene, 9,9-bis(4-(2-hydroxyethoxy)-3-isobutylphenyl)fluorene, 9,9-bis(4-(2-hydroxyethoxy)-3-t-butylphenyl)fluorene, 9,9-bis[4-(2-hydroxyethoxy)-3,5-dimethylphenyl]fluorene, and 9,9-bis(4-(2-hydroxyethoxy)-3-t-butyl-5-methylphenyl)fluorene; (iii) 9,9-bis (hydroxy-C₂₋₄ alkoxy-C₅₋₁₀ cycloalkylphenyl)fluorene such as 9,9-bis(4-(2-hydroxyethoxy)-3-cyclohexylphenyl)fluorene; (iv) 9,9-bis(hydroxy-C₂₋₄ alkoxy-C₆₋₁₀ arylphenyl)fluorene such as 9,9-bis[4-(2-hydroxyethoxy)-3-phenylphenyl]fluorene and 9,9-bis[4-(2-hydroxypropoxy)-3-phenylphenyl]fluorene; and compounds in which r in the compounds (ii) to (iv) is 2 to 5, for example, 9,9-bis (hydroxy-C₂₋₄ alkoxy-C₂₋₄ alkoxyphenyl) fluorene, 9,9-bis (hydroxy-C₂₋₄ alkoxy-C₂₋₄ alkoxy-mono- or di-C₁₋₄ alkylphenyl)fluorene, and 9,9-bis(hydroxy-C₂₋₄ alkoxy-C₂₋₄ alkoxy-C₆₋₁₀ arylphenyl)fluorene.

Examples of the 9,9-bis(hydroxy(poly)alkoxynaphthyl)fluorenes include: 9,9-bis(hydroxyalkoxynaphthyl)fluorene [e.g., 9,9-bis(hydroxy-C₂₋₄ alkoxynaphthyl)fluorene such as 9,9-bis[6-(2-hydroxyethoxy)-2-naphthyl]fluorene, 9,9-bis[5-(2-hydroxyethoxy)-1-naphthyl]fluorene, and 9,9-bis[6-(2-hydroxypropoxy)-2-naphthyl]fluorene]; and compounds in which r is 2 to 5, for example, 9, 9-bis (hydroxy-C₂₋₄ alkoxy-C₂₋₄ alkoxynaphthyl)fluorene.

These diol components (A) can each be used singly, or two or more thereof can be used in combination. The diol component (A) can be particularly preferably 9,9-bis[4-(2-hydroxyethoxy)phenyl]fluorene of the general formula (2) wherein Z is a phenylene group, each of p and q is 0, R⁴ is an ethylene group, and r is 1.

In one aspect, the ratio of the diol component (A) used, though depending on the type or ratio of the dicarboxylic acid component used, is preferably 0 to 80% by mol, more preferably 0 to 50% by mol, further preferably 0 to 20% by mol, based on all diol components. When the ratio of the diol component (A) is 0% by mol or more, a glass transition temperature tends to be more improved. When the ratio of the diol component (A) is 80% by mol or less, there is a tendency to more improve moldability into a film, to decrease a photoelastic coefficient, and to enhance a property of exerting a phase difference.

### Diol Component (B)

The diol component (B) which is a monomer that may constitute the polyester resin used in the present embodiment can be represented by the following general formula (3):

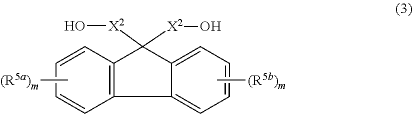

wherein R^{5a} and R^{5b} each independently represent a substituent inert to reaction, each m independently represents an integer of 0 to 4, and each X² independently represents a C₁₋₈ alkylene group.

In the general formula (3), the groups R^{5a} and R^{5b} and m are the same as R^{2a} and R^{2b} and p described in the general formula (2), also including preferred forms. X² is the same as X¹ described in the general formula (1), also including preferred forms.

Representative examples of the compound represented by the general formula (3) include 9,9-bis(hydroxymethyl)fluorene, 9,9-bis(2-hydroxyethyl)fluorene, and 9,9-bis(hydroxy-C₃₋₆ alkyl)fluorene. These diol components (B) may each be used singly, or two or more thereof may be combined. The diol component (B) is preferably 9,9-bis(hydroxymethyl)fluorene.

In one aspect, the ratio of the diol component (B) used, though depending on the type or ratio of the dicarboxylic acid component used, is preferably 0 to 80% by mol, more preferably 0 to 50% by mol, further preferably 0 to 20% by mol, based on all diol components. When the ratio of the diol component (B) falls within the range described above, a property of exerting a negative phase difference tends to be more improved.

### Diol Component (C)

The diol component (C) which is a monomer that may constitute the polyester resin used in the present embodiment can be represented by the following general formula (4):

HO—X³—OH (4)

wherein X³ represents a C₂₋₈ alkylene group.

Examples of the diol component (C) can include, but are not particularly limited to, linear or branched alkanediol (C₂₋₈ alkanediol such as ethylene glycol, 1,2-propanediol, 1,3-propanediol, 1,2-butanediol, 1,3-butanediol, 1,4-butanediol, 1,3-pentanediol, 1,4-pentanediol, 1,5-pentanediol, neopentyl glycol, and 1,6-hexanediol, preferably C₂₋₆ alkanediol, further preferably C₂₋₄ alkanediol), and polyalkanediol (e.g., di- or tri-C₂₋₄ alkanediol such as diethylene glycol, dipropylene glycol, and triethylene glycol). These diol components (C) may each be used singly, or two or more thereof may be combined.

Among them, the diol component (C) is preferably ethylene glycol of the general formula (4) wherein X³ is an ethylene group. By use of such a diol component (C), drawability tends to be more improved.

In one aspect, the ratio of the diol component (C) used, though depending on the type or ratio of the dicarboxylic acid component used, can be selected from a range, for example, on the order of 10% by mol or more (e.g., 30 to 100% by mol) based on all diol components and may be, for example, on the order of 50% by mol or more (e.g., 60 to 99% by mol), preferably 70% by mol or more (e.g., 80 to 98% by mol), further preferably 90% by mol or more (e.g., 95 to 97% by mol), particularly, 100% by mol, i.e., the diol components may be substantially constituted by only the diol component (C).

In another aspect, the ratio of the diol component (C) used is preferably 5 to 50% by mol, more preferably 5 to 35% by mol, further preferably 15 to 25% by mol, based on all diol components.

By use of the diol component (C) at the ratio as described above, though depending on the type or ratio of the dicarboxylic acid component used, the flexibility of the phase difference film tends to be more improved.

### Other Additives

The phase difference film of the present embodiment may be supplemented, if necessary, with various additives. Examples of the additives include plasticizers, flame retardants, stabilizers, antistatic agents, fillers, foaming agents, antifoaming agents, lubricants, mold release agents, and slipping agents.

Examples of the plasticizers include esters, phthalic acid compounds, epoxy compounds, and sulfonamides. Examples of the flame retardants include inorganic flame retardants, organic flame retardants, and colloidal flame retardant substances.

Examples of the stabilizers include antioxidants, ultraviolet absorbers, and heat stabilizers. Examples of the fillers include oxide-based inorganic fillers, non-oxide-based inorganic fillers, and metal powders.

Examples of the mold release agents include natural waxes, synthetic waxes, linear fatty acids and metal salts thereof, and acid amides.

Examples of the slipping agents include: inorganic fine particles such as silica, titanium oxide, calcium carbonate, clay, mica, and kaolin; and organic fine particles such as (meth)acrylic resins and styrene-based resins (cross-linked polystyrene resins, etc.). These additives may each be used singly, or two or more thereof may be used in combination.

The ratio of such an additive is, for example, 30 parts by mass or less, preferably 0.1 to 20 parts by mass, further preferably 1 to 10 parts by mass, per 100 parts by mass of the polyester resin.

### Method for Producing Polyester Resin

The polyester resin can be prepared through the reaction of a dicarboxylic acid component and a diol component. The method for producing the polyester resin is not particularly limited, and the polyester resin may be prepared by a common method, for example, a transesterification method, a melt polymerization method such as a direct polymerization method, a solution polymerization method, or an interfacial polymerization method. In the polymerization reaction, a transesterification catalyst, a polycondensation catalyst, a heat stabilizer, a light stabilizer, a polymerization modifier, or the like may be used.

Examples of the transesterification catalyst include, but are not particularly limited to, compounds (alkoxide, organic acid salt, inorganic acid salt, metal oxide, etc.) of alkaline earth metals (magnesium, calcium, barium, etc.) or transition metals (manganese, zinc, cobalt, titanium, etc.). Among them, manganese acetate, calcium acetate, or the like can be suitably used.

Examples of the type of the polycondensation catalyst can include, but are not particularly limited to, compounds of the alkaline earth metals, the transition metals, group 13 metals of the periodic table (aluminum, etc.), group 14 metals of the periodic table (germanium, etc.), or group 15 metals of the periodic table (antimony, etc.), more specifically, germanium compounds such as germanium dioxide, germanium hydroxide, germanium oxalate, germanium tetraethoxide, and germanium n-butoxide, antimony compounds such as antimony trioxide, antimony acetate, and antimony ethylene glycolate, and titanium compounds such as tetra-n-propyl titanate, tetraisopropyl titanate, tetra-n-butyl titanate, titanium oxalate, and titanium potassium oxalate. These catalysts may each be used singly, or two or more types thereof may be used as a mixture.

Examples of the heat stabilizer can include, but are not particularly limited to, phosphorus compounds such as trimethyl phosphate, triethyl phosphate, triphenyl phosphate, phosphorus acid, trimethyl phosphite, and triethyl phosphite.

In the reaction, the ratios of the dicarboxylic acid component and the diol component used can be selected from the same ranges as above. If necessary, a predetermined component may be used in excess. For example, a diol component, such as ethylene glycol, capable of being distilled off from the reaction system may be used in excess over the ratio of the unit to be introduced in the polyester resin. The reaction may be performed in the presence or absence of a solvent.

The reaction can be performed in an inert gas (nitrogen, helium, etc.) atmosphere. The reaction can also be performed under reduced pressure (e.g., on the order of 1×10² to 1×10⁴ Pa). The reaction temperature depends on a polymerization method, and the reaction temperature in a melt polymerization method, for example, may be on the order of 150 to 300° C., preferably 180 to 290° C., further preferably 200 to 280° C.

The composition containing a polyester resin having arylated fluorene in a side chain may be a polymer alloy comprising the polyester resin having arylated fluorene in a side chain, and a polycarbonate resin. The composition of the polycarbonate resin is not particularly limited as long as the polycarbonate resin is compatible with the polyester resin. For example, bisphenol A, an aromatic polycarbonate resin having a fluorene structure, or an alicyclic polycarbonate resin having an isosorbide structure can be used. If necessary, the polymer alloy may further comprise an additional resin, in addition to the polyester resin having arylated fluorene in a side chain, and the polycarbonate resin. The optical characteristics, for example, a property of exerting a phase difference, of such a polyester resin in the form of a polymer alloy can be suitably controlled.

In the polymer alloy, the ratios of the polyester resin and the polycarbonate resin are not particularly limited as long as the polyester resin and the polycarbonate resin are compatible with each other. For example, the ratio of the polyester resin is preferably 30% by weight or more, 50% by weight or more, 60% by weight or more, 70% by weight or more, 80% by weight or more, 90% by weight or more, 95% by weight or more, or substantially 100% by weight, based on the total amount of the polyester resin and the polycarbonate resin.

A method for preparing the polymer alloy is not particularly limited and may be a common method, for example, a method of dissolving both the resin components in a solvent, or a method of melt-mixing the resin components using a kneader (or an extruder, for example, a twin-screw extruder). A melt mixing method is preferred because reduction in optical characteristics (e.g., low birefringence and high transparency) caused by a residual solvent after molding into a film can be prevented.

### Form of Phase Difference Film

The phase difference film is classified, depending on the intrinsic birefringence of its material and a drawing method, into a positive A plate, a negative A plate, a positive B plate, a negative B plate, a positive C plate, a negative C plate, and the like. These plates are used in combination for each purpose of a display apparatus. A material having negative intrinsic birefringence can be uniaxially drawn into a negative A plate or a positive B plate and biaxially drawn into a positive C plate.

The negative A plate refers to a plate in which when an in-plane direction of the phase difference film that exhibits a maximum refractive index is defined as an X axis, a direction orthogonal to the X axis is defined as a Y axis, and a thickness direction is defined as a Z axis, a refractive index (nx) of the X axis, a refractive index (ny) of the Y axis, and a refractive index (nz) of the Z axis satisfy a relationship represented by the following expression (5):

nx=nz>ny (5)

The negative A plate is used, for example, for suppressing reduction in contrast caused by outside light reflection in an organic EL display apparatus.

The positive B plate refers to a plate that satisfies a relationship represented by the following expression (6):

nz>nx>ny (6)

The positive B plate is used, for example, for optical compensation that prevents reduction in contrast or color change caused by a viewing angle in a liquid crystal display apparatus having a liquid crystal cell of an in-plane switching (IPS) system.

The positive C plate refers to a plate that satisfies a relationship represented by the following expression (7):

nx=ny<nz (7)

The positive C plate is used, for example, for adjusting only a phase difference value in a thickness direction (Rth) while maintaining a phase difference value in an in-plane direction (Ro) adjusted by the phase difference film.

The description “nx=ny” for the positive C plate in the expression (7) is not only the case where the in-plane refractive index (nx) and refractive index (ny) are strictly equal, but may be the case where nx and ny are substantially equal. The description “nz=nx” in the expression (5) does not necessarily require that the in-plane refractive index (nx or ny) and the refractive index (nz) in a thickness direction should be completely consistent. Meanwhile, a Nz coefficient is defined as (nx−nz)/(nx−ny). When the Nz coefficient is larger than −0.1 and less than 0.1, the resulting film can be regarded as a negative A plate of nx=nz. When the Nz coefficient is less than −10, the resulting film can be regarded as a positive C plate of nx=ny.

The drawn phase difference film of the present embodiment can be laminated, for use, with a liquid crystal phase difference layer made of an oriented liquid crystal material. The orientation direction of the liquid crystal material is not particularly limited. The liquid crystal material may be oriented in a horizontal (homogeneous) direction with respect to the film surface, thereby suitably controlling Ro, and may be oriented perpendicularly (homeotropically) to the film surface, thereby suitably controlling Rth.

The liquid crystal material can be a material conventionally known in the field of phase difference films, and a polymerizable liquid crystal compound may be polymerized or cross-linked so that the orientation direction is fixed. Owing to the fixed orientation direction, a stable liquid crystal phase difference layer without change in optical characteristics caused by influence such as temperature change can be obtained.

A method for orienting the liquid crystal material can be a method conventionally known in the field of phase difference films and is not particularly limited. For example, a method such as rubbing treatment, drawing treatment, magnetic field orientation treatment, electric field orientation treatment, oblique evaporation, or photo-alignment treatment can be used.

The phase difference film of the present embodiment may be a ¼λ phase difference film having a function of converting linearly polarized light to circularly polarized light, or converting circularly polarized light to linearly polarized light. The ¼λ phase difference film is a phase difference film that exhibits in-plane phase difference Ro(λ) at a predetermined wavelength of λ nm=λ/4 (or an odd multiple thereof). The phase difference film of the present embodiment can be prepared as a ¼λ phase difference film appropriate for a purpose by controlling not only a chemical structure but drawing conditions such as a drawing temperature and a drawing rate, or a film thickness to be obtained after drawing, etc.

The ¼λ phase difference film may be used as a circularly polarizing plate by lamination with a polarizer. The circularly polarizing plate is disposed on the visible side of an organic EL display apparatus and used for suppressing reduction in contrast caused by outside light reflection. The organic EL display apparatus has the circularly polarizing plate and an organic EL panel consisting of an organic EL device. In the organic EL display apparatus, a polarizer, the phase difference film, and a metal electrode, etc. of an organic EL panel are located in order from the visible side.

The relationship between light incident from the visible side and the display apparatus will be described. Outside light incident from the visible side is converted to linearly polarized light by a polarizer through which only light polarized in a specific direction passes, and then converted to circularly polarized light by the phase difference film. The circularly polarized light converted from the incident light reaches a metal electrode, etc. of an organic EL panel and is reflected by the metal electrode, etc. having a property of reflecting light. By this reflection, the incident light is converted to reflected light having an inverted circularly polarized light state. Then, the reflected light having an inverted circularly polarized light state repasses through the phase difference film and is converted to reflected light of linearly polarized light inclined 90° with respect to that at the time of incidence. The reflected light of linearly polarized light inclined 90° reaches a polarizer through which only light of 0° passes, and is thereby absorbed to the polarizer so that penetration to the visible side is blocked. Owing to this series of steps, outside light incident from the visible side can no longer penetrate to the visible side even if reflected by the metal electrode, etc. of the organic EL panel. By this action, the display apparatus can keep a contrast high from the visible side without reflecting outside light.

The outside light incident from the visible side is generally supposed to have light at any wavelength in visible light region λ=400 to 780 nm. The phase difference film can perform optical compensation with higher accuracy by controlling a predetermined phase difference against the entire visible light region. For example, in a ¼λ phase difference film, phase difference λ/4 (nm) in the entire visible light region is reportedly ideal for the phase difference film.

In this context, the wavelength dispersibility refers to the relationship between a wavelength and a phase difference. A property of increasing an absolute value of the phase difference with increase in wavelength is called reverse wavelength dispersibility. For example, a property of attaining phase difference λ/4 (nm) in the entire visible light region allows the phase difference film to have reverse wavelength dispersibility in the entire visible light region. This λ/4 phase difference film having reverse wavelength dispersibility may be designed by drawing a multilayer film comprising a polymer monomer having positive intrinsic birefringence and a polymer monomer having negative intrinsic birefringence because such a phase difference film is difficult to constitute by only an existing single polymer material.

The phase difference film of the present embodiment may be a one-layer phase difference film or may be a phase difference film comprising multiple layers as long as at least one layer comprises the polyester resin. Particularly, a phase difference film for an organic EL display purpose is preferably a multilayer film comprising the polyester resin and an additional resin. The resulting phase difference film, albeit being a multilayer film, can be thinner than a conventional phase difference film and is excellent in reverse wavelength dispersibility.

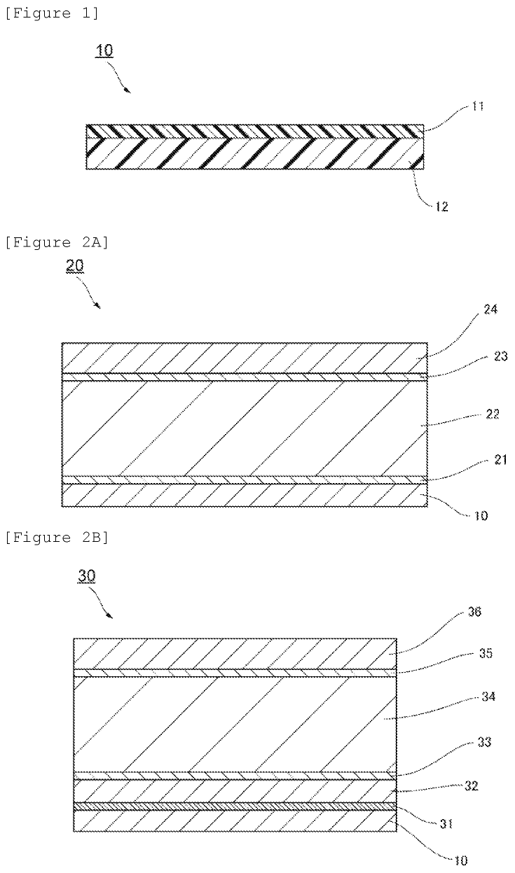

Particularly, the phase difference film comprising multiple layers is preferably, as shown in FIG. 1, a multilayer film (phase difference film 10) comprising layer 11 comprising the polyester resin, and resin layer 12 having positive intrinsic birefringence. FIG. 1 is a cross-sectional view schematically illustrating a ¼λ phase difference film according to one aspect of the present embodiment. Such a multilayer film can be a thin ¼λ phase difference film that has a smaller total thickness than that of a conventional phase difference film subjected to orientation treatment, and exhibits reverse dispersibility as the wavelength dispersion of a phase difference. Such a phase difference film can have a viewing angle compensation function by lamination with a polarizing plate.

FIG. 1 illustrates a phase difference film having one polyester resin layer 11 and one resin layer 12 having positive intrinsic birefringence. The phase difference film 10 comprising multiple layers may be a 3-layer or more multilayer phase difference film further comprising an additional layer that is not shown in FIG. 1. Alternatively, the phase difference film may be a 3-layer or more multilayer phase difference film comprising two or more individual polyester resin layers 11 and two or more individual resin layers 12 having positive intrinsic birefringence.

When the phase difference film is laminated with a base material film so as to function as a laminated film, the base material film itself serves as a phase difference film and may also be used as a support. Examples of such a laminated film include a viewing angle compensation film for an IPS mode obtained by the lamination of the base material film and a negative B plate, and a ¼λ phase difference film of an OLED circularly polarizing plate obtained by the lamination of the base material film and a positive A plate. In this case, the material of the base material film is preferably a resin having positive intrinsic birefringence, and many polymers correspond thereto. Examples thereof include polycarbonate-based resins, polyamide-based resins, polyvinyl alcohol-based resins, cellulose ester-based resins such as triacetylcellulose films and cellulose acetate propionate films, polyester-based resins such as polyethylene terephthalate and polyethylene naphthalate, polyarylate-based resins, polyimide-based resins, cycloolefin-based resins, polysulfone-based resins, polyethersulfone-based resins, and polyolefin-based resins such as polyethylene and polypropylene. Among them, particularly, a polycarbonate-based resin or a polyamide-based resin is more preferred, and a polyamide-based resin is further preferred, because of excellent drawability. The polycarbonate-based resin is excellent in film formability and adhesion to the phase difference film, and the polyamide-based resin is excellent in chemical resistance. Therefore, a wide range of solvents can be used for coating with a layer comprising the polyester resin.

When the base material film is peeled off and transferred (affixed) to another film for use, the base material film is not particularly limited as long as the film has favorable peelability, regardless of optical characteristics. Examples of such a base material film that can be used include, but are not particularly limited to, known films such as polyethylene terephthalate, polybutylene terephthalate, polyethylene naphthalate, polyethylene films, polypropylene films, cellophane, diacetylcellulose films, triacetylcellulose films, acetylcellulose butyrate films, polyvinyl chloride films, polyvinylidene chloride films, polyvinyl alcohol films, ethylene-vinyl acetate copolymer films, polystyrene films, polymethylpentene films, polysulfone films, polyether ether ketone films, polyethersulfone films, polyetherimide films, polyimide films, fluorine resin films, and nylon films. Among them, polyethylene terephthalate or a triacetylcellulose film is preferred.

In the case of producing a raw film (film before drawing) of the phase difference film of the present embodiment as a single-layer film of the polyester resin, examples of the film formation method (or the film formation process) include, but are not particularly limited to, casting methods (or solution casting methods), extrusion methods (melt extrusion methods such as inflation methods and T die methods), and calendering methods. A melt extrusion method such as a T die method is preferred from the viewpoint that not only is productivity excellent but reduction in optical characteristics caused by a residual solvent can be prevented.

In the case of producing the raw film as a laminated film of a layer comprising the polyester resin and a base material, examples of the film formation method include coextrusion molding methods, coating molding methods, extrusion lamination molding methods, and lamination methods.

In the coextrusion molding method, for example, a base material resin and the polyester resin are individually melt-extruded using an extruder, combined in a feed block, and coextrusion-molded into a film using a T die.

In the coating molding method, a base material film is coated with a solution containing the polyester resin, and the solvent is volatilized by drying to form a layer comprising the polyester resin.

In the extrusion lamination molding method, the polyester resin melt-extruded into a film on a base material film, and the base material film are sandwiched between a cooling roll and a pressure roll and thereby molded into a multilayer film.

In the lamination method, films of a layer comprising the polyester resin and a base material are separately formed by an arbitrary method, then sandwiched between pressure rolls, and thereby molded into a multilayer film. In this respect, the pressure rolls may be heated in order to improve the adhesive property between the layers.

Among them, the coextrusion molding method is preferred from the viewpoint of production efficiency and from the viewpoint of inhibiting a volatile component such as a solvent from remaining in the film. The coextrusion molding method may be limited by a resin that can be used, due to an interfacial adhesive property. The coating molding method is preferred from the viewpoint of the suppression of resin deterioration, a uniform film thickness, and the removal of foreign matter. The coating molding method may be limited by a solvent that can be used, due to the solubility of a resin.

In producing the laminated film, an adhesive layer for improving an adhesive property may be disposed between the layer comprising the polyester resin and the base material.

The material of the adhesive layer is not particularly limited as long as the material has a favorable adhesive property to the layer comprising the polyester resin and the base material. Examples thereof include polycarbonate-based resins, polyamide-based resins, polyvinyl alcohol-based resins, cellulose ester-based resins such as triacetylcellulose films and cellulose acetate propionate films, polyester-based resins such as polyethylene terephthalate and polyethylene naphthalate, polyarylate-based resins, polyimide-based resins, cycloolefin-based resins, polysulfone-based resins, polyethersulfone-based resins, and polyolefin-based resins such as polyethylene and polypropylene.

A film formation method for a laminated film comprising 3 layers, the layer comprising the polyester resin, the adhesive layer, and the base material, is not particularly limited. For example, a laminated film comprising two adjacent layers may be prepared by a method such as a coextrusion molding method, a coating molding method, or an extrusion lamination molding method, and the third layer can then be formed in another step, or films of the 3 layers may be formed at the same time by a method such as a coextrusion molding method in order to improve productivity.

Examples of the coextrusion T die method which is a coextrusion molding method include feed block methods and multi-manifold methods. A multi-manifold method is particularly preferred because variation in thickness of each layer can be reduced. In the case of producing a laminated film using the coextrusion molding method, the melting temperature of a resin to be extruded is preferably Tg+80° C. or higher, more preferably Tg+100° C. or higher, and preferably Tg+180° C. or lower, more preferably Tg+150° C. or lower. The melting temperature, for example, in the coextrusion T die method, refers to the melting temperature of a resin in an extruder having a T die. When the melting temperature of the resin to be extruded is equal to or higher than the lower limit value of the range described above, the fluidity of the resin can be sufficiently enhanced and moldability can thus be favorable. When the melting temperature is equal to or lower than the upper limit value, the deterioration of the resin can be suppressed.

In the coextrusion molding method, a melted resin in a film form extruded from a die slip is usually cooled and cured by adhesion to a cooling roll. In this respect, examples of the method for allowing the melted resin to adhere to a cooling roll include air knife methods, vacuum box methods, and electrostatic adhesion methods.

In the coating molding method, surface roughening treatment by a sandblast method, a solvent treatment method, or the like, or surface oxidation treatment, for example, corona discharge treatment, chromic acid treatment, flame treatment, hot-air treatment, ozone/ultraviolet irradiation treatment, or electron beam irradiation treatment, may be carried out for the purpose of improving the adhesion between the polyester resin and the base material film.

Examples of the solvent for the polyester resin in the coating molding method include: aromatic solvents such as benzene, toluene, and xylene; ketone-based solvents such as diacetone alcohol, acetone, cyclohexanone, cyclopentanone, methyl ethyl ketone, and methyl isopropyl ketone; cycloalkane-based solvents such as cyclohexane, ethylcyclohexane, and 1,2-dimethylcyclohexane; halogen-containing solvents such as methylene chloride and chloroform; and ether-based solvents such as tetrahydrofuran and dioxane. The concentration of the resin in a coating liquid can be 1% by weight to 50% by weight from the viewpoint of obtaining a viscosity suitable for coating. One type of solvent may be used singly, or two or more types of solvents may be used in combination at an arbitrary ratio.

A coating method using the coating liquid is not limited. Examples of the coating method include curtain coating methods, extrusion coating methods, roll coating methods, spin coating methods, dip coating methods, bar coating methods, spray coating methods, slide coating methods, printing coating methods, gravure coating methods, die coating methods, gap coating methods, and dipping methods.

A method for drying the coating liquid is not limited. For example, a drying method such as drying by heating or drying under reduced pressure can be used.

### Method for Drawing Phase Difference Film

The phase difference film of the present embodiment preferably comprises a drawing step of drawing a film having a first resin layer containing a polyester resin having arylated fluorene in a side chain in a direction of 45°±15° with respect to a width direction.

In general, a circularly polarizing plate comprising a laminate of a polarizer and a phase difference film is often designed such that a direction in which the polarizer absorbs light is oblique to a direction in which the phase difference film causes a phase difference in the light. This polarizer is often produced so as to have the direction of light absorption in a longitudinal direction. When the direction in which the phase difference film causes a phase difference in the light is a longitudinal or a parallel direction, the phase difference film must be cut in an oblique direction for the lamination of the polarizer and the phase difference film.

However, if the phase difference film is cut in an oblique direction, many end parts of the phase difference film are generated and become an enormous loss in large-scale production.

Accordingly, the phase difference film for use as a portion of a circularly polarizing plate is drawn in a direction of 45°±15° with respect to a width direction and allowed to exert a phase difference in this direction. As a result, a loss of end parts in the lamination step with the polarizer can be drastically reduced. This also permits continuous production of a long phase difference film to be drawn in an oblique direction, and therefore markedly improves productivity.

Particularly, the phase difference film of the present embodiment has a high property of exerting a phase difference and is thin. Therefore, the phase difference film of the present embodiment requires a lower cost than that of a phase difference film or the like having the liquid crystal layer mentioned above, and is capable of reducing a production cost through continuous production by oblique drawing, as compared with liquid crystals which require many steps.

The phase difference film of the present embodiment can be uniaxially drawn into a negative A plate and a positive B plate. The uniaxial drawing may be any of fixed-end uniaxial drawing and free-end uniaxial drawing. Fixed-end uniaxial drawing is preferred because there is less neck-in and physical property values are easily adjusted. The direction of drawing may be any of longitudinal drawing which draws the film in a longitudinal direction, transverse drawing which draws the film in a width direction, and oblique drawing which draws the film in an oblique direction (e.g., a direction that forms an angle of 45° with respect to the longitudinal direction). A drawing method is not particularly limited and may be a common method such as an inter-roll drawing method, a heating roll drawing method, a compression drawing method, or a tenter drawing method.

In the case of uniaxial drawing, the drawing temperature also differs depending on the desired phase difference and may be, for example, on the order of (Tg−10) to (Tg+20)° C., preferably (Tg−5) to (Tg+10)° C., further preferably (Tg−3) to (Tg+5)° C. (e.g., (Tg+2) to (Tg+5)° C.). Specifically, the temperature may be, for example, on the order of 100 to 150° C., preferably 110 to 145° C., further preferably 120 to 140° C. (e.g., 129 to 133° C.). When the drawing temperature falls within the range mentioned above, not only is the desired phase difference more easily exerted, but the film can be more uniformly drawn and can be more prevented from being broken.

In the case of uniaxial drawing, the draw ratio also differs depending on the desired phase difference and may be, for example, on the order of 1.1 to 5 times, preferably 1.3 to 3.5 times, further preferably 1.5 to 2.5 times. When the draw ratio is equal to or more than the lower limit value described above, the desired phase difference is more easily obtained. When the draw ratio is equal to or less than the upper limit value described above, elevation in phase difference and break of the film can be more suppressed. The phase difference film of the present embodiment is difficult to break because of favorable drawability and toughness, and, albeit being a thin film, produces the desired phase difference because of a high property of exerting a phase difference.

In the case of uniaxial drawing, the drawing rate may be, for example, on the order of 1 to 100 mm/min, preferably 20 to 80 mm/min, further preferably 50 to 70 mm/min. When the drawing rate is equal to or more than the lower limit value described above, the desired phase difference is more easily obtained.

The phase difference film of the present embodiment can be biaxially drawn into a positive C plate. The biaxial drawing may be any of sequential biaxial drawing and simultaneous biaxial drawing. In the sequential biaxial drawing, longitudinal drawing is usually performed by inter-roll drawing, followed by transverse drawing by tenter drawing. The inter-roll drawing causes neck-in and has a disadvantage such as the transfer of a scratch by contact with a roll. The simultaneous biaxial drawing has a disadvantage such as neck-in between clips at both ends of the film. The simultaneous biaxial drawing is preferred for an almost zero in-plane phase difference.

In the case of biaxial drawing, the drawing temperature may be, for example, on the order of (Tg−10) to (Tg+20)° C., preferably (Tg−5) to (Tg+10)° C., further preferably (Tg−3) to (Tg+5)° C. (e.g., (Tg+2) to (Tg+5)° C.). Specifically, the temperature may be, for example, on the order of 100 to 150° C., preferably 110 to 145° C., further preferably 120 to 140° C. (e.g., 129 to 133° C.). When the drawing temperature falls within the range mentioned above, not only is the desired phase difference more easily exerted, but the film can be more uniformly drawn and can be more prevented from being broken.

In the case of biaxial drawing, the draw ratio also differs depending on the desired phase difference and is preferably equal times longitudinally and transversely for a zero in-plane phase difference. The draw ratio may be, for example, on the order of 1.1 to 5×1.1 to 5 times, preferably 1.3 to 3.5×1.3 to 3.5 times, further preferably 1.5 to 2.5×1.5 to 2.5 times. When the draw ratio is equal to or more than the lower limit value described above, the desired phase difference is easily obtained. When the draw ratio is equal to or less than the upper limit value described above, elevation in phase difference and break of the film can be more suppressed. The phase difference film of the present embodiment is difficult to break because of favorable drawability and toughness, and, albeit being a thin film, produces the desired phase difference because of a high property of exerting a phase difference.

In the case of biaxial drawing, the drawing rate may be equal rates longitudinally and transversely for a zero in-plane phase difference. The drawing rate may be, for example, on the order of 1 to 100 mm/min, preferably 20 to 80 mm/min, further preferably 50 to 70 mm/min. When the drawing rate is equal to or more than the lower limit value described above, the resulting film tends to have a larger phase difference. When the drawing rate is equal to or less than the upper limit value described above, break of the film tends to be more suppressed. The phase difference film of the present embodiment is difficult to break because of favorable drawability and toughness, and, albeit being a thin film, produces the desired phase difference because of a high property of exerting a phase difference.

The phase difference film may be laminated, if necessary, with an additional film (or a coating layer) without impairing the advantageous effects of the present invention. For example, the surface of the phase difference film may be coated with a polymer layer containing a surfactant, a mold release agent, or fine particles to form a slipping layer.

The film comprising the polyester resin (or the resin layer) of the present embodiment can be formed as a thin film and exhibits a large phase difference even in the form of a thin film. Hence, the thickness of the film or the resin layer before drawing can be selected from a range, for example, on the order of 3 to 20 μm (e.g., 5 to 10 μm). The thickness of the phase difference film (or the layer comprising the polyester resin) after drawing may be, for example, on the order of 1 to 10 μm (e.g., 2 to 8 μm), preferably 1.5 to 8 μm (e.g., 3 to 5 μm), further preferably 2.0 to 5 μm (e.g., 2.5 to 3.5 μm).

The total thickness of the single-layer or multilayer phase difference film after drawing is preferably 1 to 50 μm, more preferably 5 to 40 μm, further preferably 10 to 35 μm. Use of the polyester resin of the present embodiment can achieve such a more thinned phase difference film.

The phase difference film of the present embodiment has negative intrinsic birefringence and a high property of exerting a phase difference and can therefore prepare a thin negative phase difference film (negative A plate, positive B plate, or positive C plate) by changing a drawing method. Such a phase difference film can be suitably used in a viewing angle compensation plate for liquid crystal displays, or for viewing angle compensation of a circularly polarizing plate for organic EL displays.

The phase difference film of the present embodiment can be prepared as a conductive phase difference film by forming a transparent conductive layer on one side or both sides thereof. The conductive phase difference film can have not only a function as the phase difference film but a function as an electrode for components of electronics such as touch panels, a function as an electromagnetic wave shield which blocks electromagnetic wave responsible for the malfunction of electronics, and the like.

The transparent conductive layer is not particularly limited as long as the transparent conductive layer has high conductivity and high transparency. The transparent conductive layer may comprise, for example, a plurality of metal thin wires formed therein.

The metal thin wires are preferably silver, copper, or an alloy comprising at least one thereof because of excellent conductivity. Use of such a metal material excellent in conductivity can confer sufficient conductivity even if the line width of the metal thin wires is thinned in order to enhance transparency.

A method for forming the metal thin wires is not particularly limited. For example, a formation method of pattern-exposing a layer made of a photosensitive material such as silver halide, followed by development treatment, a formation method of pattern-etching a conductive layer formed by deposition, sputtering, metal foil lamination, or the like, or a formation method of printing metal ink containing metal nanowires by an inkjet method or a method such as screen printing, can be used.

The line width of the metal thin wires is not particularly limited and is preferably 1 to 20 μm, more preferably 1 to 10 μm, further preferably 1 to 5 μm, from the viewpoint of exerting high conductivity and rendering the metal thin wires less visible.

The transparent conductive layer may comprise indium tin oxide (ITO), antimony-doped tin oxide (ATO), a conductive polymer, or a carbon-based material, in addition to the formed metal thin wires mentioned above. Use of such a material can prepare a transparent conductive layer having sufficient conductivity even if the transparent conductive layer is thinned so as to have a thickness that attains transparency. Among them, indium tin oxide is preferably used because of having high conductivity and transparency. Such a transparent conductive layer can be formed as a thin film by a method such as deposition or sputtering and may be further patterned, if necessary, after thin film formation.

### Polarizing Plate

Next, the polarizing plate of the present embodiment will be described with reference to FIGS. 2A and 2B. This polarizing plate comprises the phase difference film described above. Each of FIGS. 2A and 2B is a cross-sectional view schematically illustrating one form of the polarizing plate.

Polarizing plate 20 shown in FIG. 2A is a laminate of phase difference film 10, polarizer 22, and polarizer protective film 24. As shown in this drawing, adhesive layer 21 may be disposed between the phase difference film 10 and the polarizer 22, and adhesive layer 23 may be disposed between the polarizer 22 and the polarizer protective film 24.

Polarizing plate 30 shown in FIG. 2B is a laminate of phase difference film 10, polarizer protective film 32, polarizer 34, and polarizer protective film 36. Adhesive layer 31 may be disposed between the phase difference film 10 and the polarizer protective film 32, and adhesive layer 33 or 35 may be disposed between the polarizer 34 and the polarizer protective film 32 or 36.

The phase difference film 10 may be subjected to corona treatment, plasma treatment, or surface modification treatment with an aqueous solution of a strong base such as sodium hydroxide or potassium hydroxide in order to improve adhesion to the polarizer 22. Such adhesive layer formation or surface modification treatment may be performed after a film formation step or may be performed after a drawing step.

The polarizer 22 is not particularly limited as long as the polarizer is a conventionally known one. Examples thereof include: films obtained by subjecting hydrophilic polymer films such as polyvinyl alcohol films, partially formalized polyvinyl alcohol films, or ethylene-vinyl acetate copolymer-based partially saponified films to staining treatment with iodine or a dichroic substance such as a dichroic dye and drawing treatment; and polyene-based oriented films such as dehydration treatment products of polyvinyl alcohol and dehydrochlorination treatment products of polyvinyl chloride. Other examples thereof include polarizers obtained by staining polyvinyl alcohol films with iodine, followed by uniaxial drawing.

The polarizer protective film 24 is not particularly limited as long as the material has a high adhesive property to the polarizer 22 and is optically transparent. Examples thereof include cellulose ester-based films such as triacetylcellulose films and cellulose acetate propionate films, modified acrylic resin-based films, ultrahigh-birefringence polyethylene terephthalate resin-based films, and cycloolefin-based films.

The polarizing plate of the present embodiment may further comprise a ¼λ phase difference film on the visible side of the phase difference film. Such a configuration of the phase difference film of the present embodiment further laminated with the ¼λ phase difference film can circularly polarize light from a backlight of an organic EL display apparatus or a liquid crystal display apparatus (hereinafter, referred to as a “light emission side”).

In general, for example, a polarizing plate that linearly polarizes light is present on the visible side of a display apparatus. When a viewer wears sunglasses, so-called blackout may arise which is a problem in which no visible contact is attained if the sunglasses are orthogonal to the polarization direction of the polarizing plate. In order to avoid this problem, light from the light emission side is applied to pass through the polarizing plate so as to become linearly polarized light, which is then allowed to pass through the ¼λ phase difference film having a circular polarization function. The light with which the viewer has visible contact thereby becomes circularly polarized light so that blackout can be prevented. Such a function is also called sunglass readability.

The ¼λ phase difference film to be laminated on the visible side of the phase difference film is provided, as described above, for the purpose of avoiding blackout by circularly polarizing light from the light emission side, aside from a ¼λ phase difference film aimed at having a function of circularly polarizing incident light and reflected light in order to allow a polarizing plate to absorb reflected light in an organic EL display apparatus.

As described above, the ¼λ phase difference film has a plurality of different functions. Therefore, in order to avoid confusion, the ¼λ phase difference film aimed at having a function of circularly polarizing incident light and reflected light in order to allow a polarizing plate to absorb reflected light in an organic EL display apparatus may be referred to as a “first ¼λ phase difference film”, and the ¼λ phase difference film aimed at having a function of avoiding blackout by circularly polarizing light from the light emission side may be referred to as a “second ¼λ phase difference film”.

A surface treatment layer mentioned later may be formed, if necessary, on the surface of the second ¼λ phase difference film.

The surface treatment layer is intended to improve a function of the polarizing plate of the present embodiment. Specific examples thereof include layers having one or more of hard coat, antiglare, antireflection, low-reflection, antifouling, and anti-fingerprint effects.

A known material can be used for the layer having the hard coat effect without particular limitations, and a resin compound that is polymerized and/or reacted by heat, chemical reaction, or electron beam, radiation, or ultraviolet irradiation is suitably used. Examples of such a curable resin include (meth)acrylic, epoxy-based, melamine-based, silicone-based, and polyvinyl alcohol-based curable resins. A (meth)acrylic curable resin that is cured by electron beam or ultraviolet ray is preferred because high surface hardness or optical characteristics are obtained. The step of establishing the hard coat layer on the second ¼λ phase difference film of the present embodiment may be carried out before the drawing or may be carried out after the drawing.

The layer having the antiglare effect is not particularly limited. For example, a layer that suppresses glare and reflection by diffusely reflecting incident light from the outside through formed surface asperities can be used as a representative one. Examples of the method for forming the surface asperities include a method of directly roughening the surface by a sandblast method or an embossing method, and a method of allowing a curable resin to contain an inorganic filler (fine particles of silica, etc.) or an organic filler (fine particles of a polystyrene resin, an acrylic resin, etc.) having a diameter on the order of several pm, and curing the resin to establish asperities derived from the inorganic filler or the organic filler.

The layer having the antireflection effect is not particularly limited. For example, a layer that suppresses outside light reflection by coating a dielectric thin film (antireflection film) made of an inorganic material with multiple layers so that reflected light generated at the interface between the thin films and reflected light generated on the outermost surface interfere with each other can be used as a representative one.

The layer having the low-reflection effect is not particularly limited, and a layer that suppresses outside light reflection by reducing a refractive index of the outermost surface can be used. Examples of the method for reducing the refractive index of the outermost surface can include a method of applying a resin containing a low-refractive material typified by a fluorine-based material, and a method of lowering the refractive index by forming a structure finer than the wavelength of visible light on the surface and thereby substantially setting the refractive index of the surface to an average refractive index with air in the fine structure.

The layer having the antifouling effect or the anti-fingerprint effect is not particularly limited, and a layer formed by dry coating or wet coating with a material excellent in water repellency or oil repellency can be used. Specific examples of the material excellent in water repellency or oil repellency can include silicon compounds and fluorine compounds.

### Image Display Apparatus

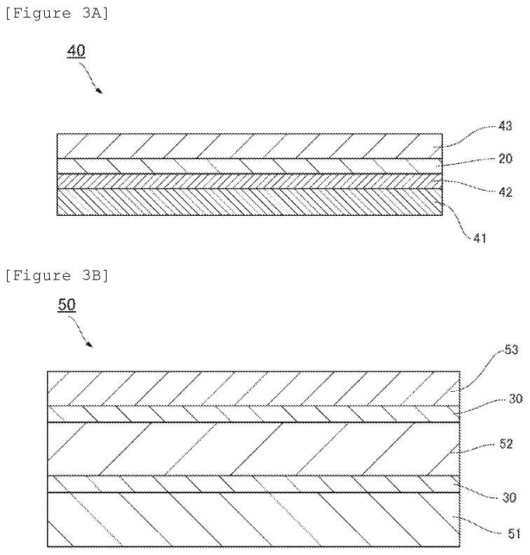

Next, the image display apparatus of the present embodiment will be described with reference to FIGS. 3A and 3B. The image display apparatus of the present embodiment is not particularly limited as long as the image display apparatus comprises the polarizing plate. Examples thereof include organic electroluminescence (EL) display apparatuses and liquid crystal display apparatuses. The image display apparatus is not only an apparatus that is distributed as a final product in itself to the market but may be a portion of an information processing apparatus mentioned later, for example, a smartphone. FIG. 3A is a cross-sectional view schematically illustrating an organic EL display apparatus according to one aspect of the present embodiment. FIG. 3B is a cross-sectional view schematically illustrating a liquid crystal display apparatus according to one aspect of the present embodiment.

As shown in FIG. 3A, organic EL display apparatus 40 has organic EL display panel 41, polarizing plate 20 comprising the phase difference film 10 of the present embodiment, and front panel 43 in this order. In the organic EL display apparatus 40, use of polarizing plate 20 having a ¼λ phase difference film suppresses outside light reflection so that less colored black can be expressed.

The organic EL display apparatus 40 may optionally have an additional configuration such as touch sensor 42. The organic EL display apparatus 40 equipped with the touch sensor 42 functions as an information input interface, in addition to a function as a display apparatus. The respective layers constituting the organic EL display apparatus 40 may be joined to each other using an adhesive.

As shown in FIG. 3B, liquid crystal display apparatus 50 has light source 51, polarizing plate 30, liquid crystal panel 52, polarizing plate 30, and front panel 53 in this order. The light source 51 may be a direct-lit system in which light sources are evenly arranged immediately beneath the liquid crystal panel, or may be an edge-lit system having a reflector and a light guide panel. Although FIG. 3B shows the front panel 53, the liquid crystal display apparatus 50 may have no front panel 53. The liquid crystal display apparatus 50 may further have a touch sensor (not shown).

The touch sensor may be a so-called in-cell touch sensor which is disposed inside the organic EL display panel 41 or the liquid crystal panel 52, or may be a so-called on-cell touch sensor which is disposed between the organic EL display panel 41 and the polarizing plate 20 or between the liquid crystal panel 52 and the polarizing plate 30. The in-cell or on-cell touch sensor is capable of reducing a thickness or a weight as compared with a conventionally dominant external touch sensor.

The system of the touch sensor is not particularly limited. For example, any of conventionally known capacitive, optical, ultrasonic, electromagnetic induction, and resistive systems can be used. Among them, a capacitive touch sensor having at least one conductive film is preferred because a plurality of locations can be detected by touch at the same time and durability is excellent.

A conductive layer formed on the surface of a base material film can be used as the conductive film. The base material film is not particularly limited as long as the conductive layer can be formed. A polyester resin, a cycloolefin resin, a polycarbonate resin, or a polyimide resin is preferably used because of high processability, etc.

The conductive layer to be formed in the conductive film is not particularly limited as long as the conductive layer has high conductivity and high transparency. The conductive layer may comprise, for example, a plurality of metal thin wires formed therein.

The metal thin wires are preferably silver, copper, or an alloy comprising at least one thereof because of excellent conductivity. Use of such a metal material excellent in conductivity can confer sufficient conductivity even if the line width of the metal thin wires is thinned in order to enhance transparency.

A method for forming the metal thin wires is not particularly limited. For example, a formation method of pattern-exposing a layer made of a photosensitive material such as silver halide, followed by development treatment, a formation method of pattern-etching a conductive layer formed by deposition, sputtering, metal foil lamination, or the like, or a formation method of printing metal ink containing metal nanowires by an inkjet method or a method such as screen printing, can be used.

The line width of the metal thin wires is not particularly limited and is preferably 1 to 20 μm, more preferably 1 to 10 μm, further preferably 1 to 5 μm, from the viewpoint of exerting high conductivity and rendering the metal thin wires less visible.

The conductive layer to be formed in the conductive film may comprise indium tin oxide (ITO), antimony-doped tin oxide (ATO), a conductive polymer, or a carbon-based material, in addition to the formed metal thin wires mentioned above. Use of such a material can prepare a transparent conductive layer having sufficient conductivity even if the transparent conductive layer is thinned so as to have a thickness that attains transparency. Among them, indium tin oxide is preferably used because of having high conductivity and transparency. Such a transparent conductive layer can be formed as a thin film by a method such as deposition or sputtering and may be further patterned, if necessary, after thin film formation.

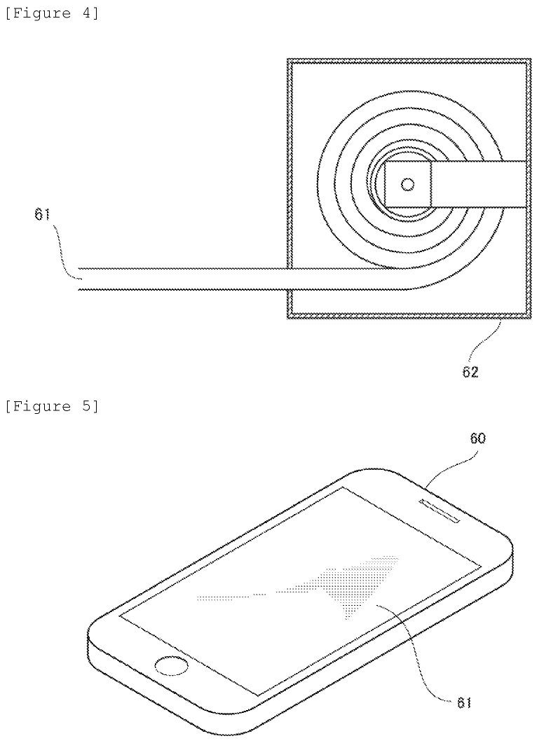

The screen of the image display apparatus is not limited by a rectangular shape and may have a round, oval, or polygonal (e.g., triangular or pentagonal) shape. The image display apparatus can further have flexibility, and its shape may be changed such that the image display apparatus is arched, bent, wound, or folded. For example, as shown in FIG. 4, the mage display apparatus includes a rollable display that can be used such that a roll of image display apparatus 61 housed in image display apparatus housing 62 is taken out.

The image display apparatus of the present embodiment has less change in optical characteristics such as staining in a high-temperature environment and as such, can be suitably used, for example, as an in-car image display apparatus such as a car navigation apparatus, a back monitor, or a head-up display.

### Information Processing Apparatus

Next, the information processing apparatus of the present embodiment will be described with reference to FIG. 5. This drawing is a perspective view schematically showing information processing apparatus 60 of the present embodiment. The information processing apparatus 60 comprises the image display apparatus having the polarizing plate. The information processing apparatus 60 is a smartphone having image display apparatus 61. The image display apparatus 61 can adopt, for example, the configuration of the organic EL display apparatus 40 or the liquid crystal display apparatus 50 mentioned above.

Examples of such information processing apparatus 60 include smartphones as well as, but are not particularly limited to, various apparatuses capable of processing information, such as personal computers and tablet terminals. The thinness of the polarizing plate of the present embodiment is exploited, particularly, for a personal computer, a smartphone, a tablet terminal, or the like desired to be thinned or miniaturized. The reverse wavelength dispersibility of the polarizing plate of the present embodiment is more exploited for a personal computer, a smartphone, a tablet terminal, or the like that is carried to various locations such as outdoors or indoors and used.

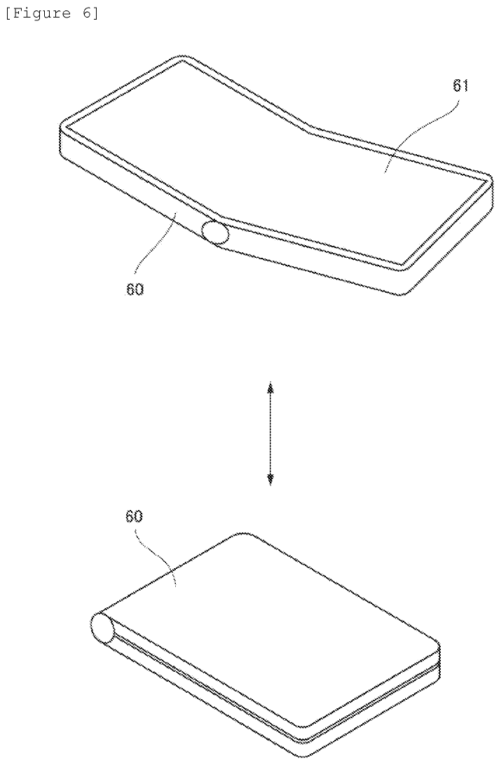

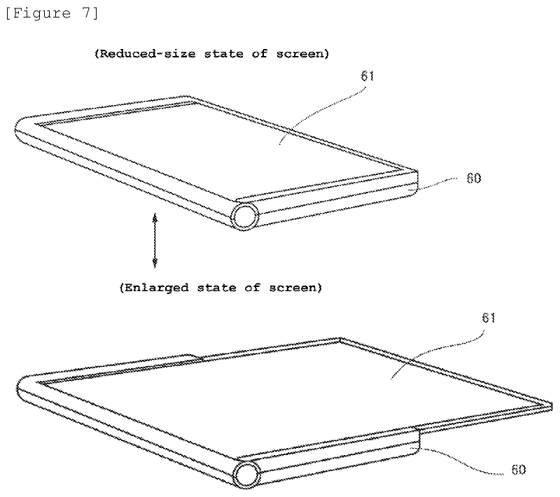

Further examples of the information processing apparatus 60 include terminals such as a foldable smartphone that has refrangible image display apparatus 61 and can be folded (FIG. 6), and a rollable smartphone that can be used such that a roll of image display apparatus 61 housed therein is taken out (FIG. 7).

The image display apparatus 61 may also have a function as an input or output interface of the information processing apparatus and may have a function as an output interface which outputs various processing results of the information processing apparatus, or an input interface, such as a touch panel, which performs operation for the information processing apparatus. Other configurations of the information processing apparatus are not particularly limited, and the information processing apparatus can typically have a processor, a communication interface that controls wired or wireless communication, an input or output interface other than the image display apparatus, a memory, a storage, and one or more communication buses for mutually connecting these components.

### EXAMPLES

Hereinafter, the present invention will be described in more detail with reference to Examples. However, the present invention is not limited by these Examples. Evaluation methods and starting materials will be given below.

### Evaluation Method

(Glass transition temperature (Tg))

A differential scanning calorimeter (“DSC 6220” manufactured by Seiko Instruments Inc.) was used. A sample was placed in an aluminum pan, and Tg was measured in the range of 30° C. to 200° C. in accordance with JIS K 7121.

### Molecular Weight

Gel permeation chromatography (manufactured by Tosoh Corp., “HLC-8120GPC”) was used. A sample was dissolved in chloroform, and polystyrene-based weight-average molecular weight Mw was measured.

### Ro, Rth, and Birefringent Characteristics

A retardation measurement apparatus (“RETS-100” manufactured by Otsuka Electronics Co., Ltd.) was used. Ro(450), Ro(550), Rth(550), nx, ny, and nz of a drawn film were measured at a measurement temperature of 20° C.

The description “nx=ny” in the birefringent characteristics is not only the case where nx and ny are strictly equal, but may encompasses the case where nx and ny are substantially equal. When a Nz coefficient according to an expression given below is less than −10, the resulting film can be regarded as a positive C plate of nx=ny.

The description “nx=nz” does not necessarily require that the in-plane refractive index (nx or ny) and the refractive index nz in a thickness direction should be completely consistent. When a Nz coefficient according to an expression give below is larger than −0.1 and less than 0.1, the resulting film can be regarded as a negative A plate of nx=nz. The Nz coefficient is a value represented by (nx−nz)/(nx−ny) unless otherwise specified.

### Average Thickness

A thickness gauge (“Micrometer” manufactured by Mitsutoyo Corp.) was used. Three equally spaced points between chucks were measured in the longitudinal direction of a film, and an average value thereof was calculated.

### Starting Material

### Synthesis Example 1: FDPm: 9,9-bis(2-methoxycarbonylethyl)fluorene [dimethyl ester of 9,9-bis(2-carboxyethyl)fluorene (or fluorene-9,9-dipropionic acid)])

200 mL of 1,4-dioxane and 33.2 g (0.2 mol) of fluorene were placed in a reactor, and the fluorene was dissolved by stirring. Then, 3.0 mL of a solution containing 40% by weight of trimethylbenzylammonium hydroxide in methanol (“Triton B40” manufactured by Tokyo Chemical Industry Co., Ltd.) was added dropwise thereto in a state cooled to 10° C., and the mixture was stirred for 30 minutes. Next, 37.9 g (0.44 mol) of methyl acrylate was added thereto, and the mixture was stirred for approximately 3 hours. After the completion of the reaction, the reaction mixture was washed by the addition of 200 mL of toluene and 50 mL of 0.5 N hydrochloric acid. The aqueous layer was removed, and the organic layer was then washed three times with 30 mL of distilled water. The solvent was distilled off to obtain 84.0 g of 9,9-bis(methyl propionate)fluorene [9,9-bis{2-(methoxycarbonyl)ethyl}fluorene] (yield: 99%). The compound was further dissolved in 300 mL of isopropyl alcohol of 70° C. and then recrystallized by cooling to 10° C. to obtain 9,9-bis(2-methoxycarbonylethyl)fluorene.

### (Synthesis Example 2: DNFDP-m: 9,9-bis(2-methoxycarbonylethyl)2,7-di(2-naphthyl)fluorene)

A reactor was charged with 192.3 g (0.39 mol) of 2,7-dibromofluorene, 200 g (1.2 mol) of 2-naphthylboronic acid, 4.3 L of dimethoxyethane, and 1 L of a 2 M aqueous sodium carbonate solution. Under a stream of nitrogen, 22.4 g (19.4 mmol) of tetrakis(triphenylphosphine)palladium(0) [or Pd(PPh₃)₄] was added thereto, and the mixture was reacted by heating to reflux at an internal temperature of 71 to 78° C. for 5 hours. After cooling to room temperature, 2.0 L of toluene and 500 mL of ion-exchange water were added thereto, followed by liquid-liquid extraction five times and washing. The color of the organic layer was changed from dark orange to brown. Insoluble matter was filtered off, and the filtrate was concentrated to obtain 305 g of brown crude crystals. The obtained crude crystals were dissolved by heating in a mixed solution of 1.5 kg of ethyl acetate and 300 g of isopropyl alcohol (IPA). Then, the solution was cooled to 10° C. or lower with ice water and stirred for 1 hour to deposit crystals. The deposited crystals were collected by filtration and then dried under reduced pressure to obtain 130 g of gray-brown crystals. The obtained gray-brown crystals were purified by column chromatography (silica gel support, developing solvent: chloroform:ethyl acetate (volume ratio)=4:1), then recrystallized with methanol, and dried under reduced pressure to obtain 116 g of 9,9-bis(2-methoxycarbonylethyl)2,7-di(2-naphthyl)fluorene (DNFDP-m) (white crystals, yield: 54.9%), HPLC purity: 99.4 area %).

Abbreviations in the description below each represent the following.
BPEF: 9,9-bis[4-(2-hydroxyethoxy)phenyl]fluorene, manufactured by Osaka Gas Chemicals Co., Ltd.
EG: ethylene glycol
PA: polyamide, TROGAMID CX7323, manufactured by Daicel-Evonik Ltd.
PC: polycarbonate, Lupilon E-2000, manufactured by Mitsubishi Engineering-Plastics Corp.

### Production Example 1

To 0.65 mol of DNFDP-m, 0.7 mol of BPEF, 0.35 mol of FDP-m, and 2.30 mol of EG, 2×10⁻⁴ mol of manganese acetate tetrahydrate and 8×10⁻⁴ mol of calcium acetate monohydrate were added as a transesterification catalyst, and the mixture was gradually melted by heating with stirring. After temperature elevation to 230° C., 14×10⁻⁴ mol of trimethyl phosphate and 20×10⁻⁴ mol of germanium oxide were added thereto, and EG was removed by gradual temperature elevation and pressure reduction until reaching 270° C. and 0.13 kPa or lower. After reaching a predetermined stirring torque, the contents were isolated from the reactor to prepare polyester resin pellets.

As a result of analyzing the obtained pellets by ¹H-NMR, 65% by mol and 35% by mol of dicarboxylic acid components introduced in the polyester resin were derived from DNFDP-m and FDP-m, respectively, and 70% by mol and 30% by mol of diol components introduced therein were derived from BPEF and EG, respectively. The obtained polyester resin had glass transition temperature Tg of 132° C. and weight-average molecular weight Mw of 90,000. This resin is referred to as resin A.

### Production Example 2

A polyester resin was prepared by the same method as in Production Example 1 except that the starting materials were changed to 1.00 mol of DNFDP-m, 0.80 mol of BPEF, and 2.20 mol of EG. As a result of analyzing the obtained pellets by ¹H-NMR, 100% by mol of dicarboxylic acid components introduced in the polyester resin was derived from DNFDP-m, and 80% by mol and 20% by mol of diol components introduced therein were derived from BPEF and EG, respectively. The obtained polyester resin had glass transition temperature Tg of 162° C. and weight-average molecular weight Mw of 90,000. This resin is referred to as resin B.

### Production Example 3

A polyester resin was prepared by the same method as in Production Example 1 except that the starting materials were changed to 0.50 mol of DNFDP-m, 0.80 mol of BPEF, 0.50 mol of FDPm, and 2.20 mol of EG. As a result of analyzing the obtained pellets by ¹H-NMR, 50% by mol and 50% by mol of dicarboxylic acid components introduced in the polyester resin were derived from DNFDP-m and FDPm, respectively, and 80% by mol and 20% by mol of diol components introduced therein were derived from BPEF and EG, respectively. The obtained polyester resin had glass transition temperature Tg of 142° C. and weight-average molecular weight Mw of 90,000. This resin is referred to as resin C.

### Production Example 4

A polyester resin was prepared by the same method as in Production Example 1 except that the starting materials were changed to 0.75 mol of DNFDP-m, 0.2 mol of BPEF, 0.25 mol of FDPm, and 2.80 mol of EG. As a result of analyzing the obtained pellets by ¹H-NMR, 75% by mol and 25% by mol of dicarboxylic acid components introduced in the polyester resin were derived from DNFDP-m and FDPm, respectively, and 20% by mol and 80% by mol of diol components introduced therein were derived from BPEF and EG, respectively. The obtained polyester resin had glass transition temperature Tg of 127° C. and weight-average molecular weight Mw of 90,000. This resin is referred to as resin D.

### Production Example 5

A polyester resin was prepared by the same method as in Production Example 1 except that the starting materials were changed to 1.00 mol of FDPm, 0.80 mol of BPEF, and 2.20 mol of EG. The obtained polyester resin had glass transition temperature Tg of 126° C. and weight-average molecular weight Mw of 43,600. This resin is referred to as resin E.

### Examples 1 to 6 and Comparative Example 1

Approximately 1 g of the pellets of each resin prepared in Production Examples 1 to 5 described above was dried, then sandwiched between two spacers of 12 cm in length, 12 cm in width, and 0.1 mm in thickness lined with a polyimide film, pressurized in vacuum for 10 minutes at a temperature higher by 20° C. to 40° C. than the glass transition temperature Tg of the resin at a pressure of 5 MPa using a vacuum heating pressure apparatus (“11FD model” manufactured by Imoto machinery Co., Ltd.), isolated together with the spacers, and cooled to prepare an undrawn film.

Each undrawn film thus obtained was subjected to free-end uniaxial drawing under the drawing conditions shown in Table 1 using a tenter drawing apparatus. Various physical properties of the obtained drawn film were measured. The results are shown in Table 1.

### Examples 7 to 10 and Comparative Examples 2 and 3

The pellets of each resin prepared in Production Examples 1, 2, 4, and 5 described above were dissolved at a concentration of 30% in tetrahydrofuran. A PA or PC film was coated with the solution using an applicator and dried at 80° C. for 8 hours to prepare an undrawn laminated film as described in Table 2.

Each undrawn film thus obtained was subjected to free-end or fixed-end uniaxial drawing under the drawing conditions shown in Table 2 using a tenter drawing apparatus. Various physical properties of the obtained drawn film were measured. The results are shown in Table 2.

TABLE 1

| | Undrawn film | | Drawing conditions | | | Film after drawing | | | | |
|---|---|---|---|---|---|---|---|---|---|---|
| | Starting | | | Drawing | | | R₀ (550 | | Rₜₕ (550 | |
| | material | Thickness | Drawing | temperature | Draw | Thickness | nm) | R₀ (450 nm)/ | nm) | Birefringent |
| | resin | [μm] | method | [° C.] | ratio | [μm] | [nm] | R₀ (550 nm) | [nm] | characteristics |
| Example 1 | Resin A | 330 | Free-end | 137 | 2.5 | 242 | 5943 | 1.30 | −2972 | nx = nz > ny |
| | | | uniaxial | | | | | | | (Negative A plate) |
| Example 2 | Resin B | 465 | Free-end | 167 | 2 | 341 | 3541 | 1.17 | −1770 | nx = nz > ny |
| | | | uniaxial | | | | | | | (Negative A plate) |
| Example 3 | Resin C | 475 | Free-end | 149 | 2 | 348 | 2583 | 1.22 | −1292 | nx = nz > ny |
| | | | uniaxial | | | | | | | (Negative A plate) |
| Example 4 | Resin D | 172 | Free-end | 132 | 2 | 128 | 2597 | 1.23 | −1274 | nx = nz > ny |
| | | | uniaxial | | | | | | | (Negative A plate) |
| Example 5 | Resin D | 200 | Fixed-end | 132 | 2 | 139 | 1381 | 1.33 | −1410 | nz > nx > ny |
| | | | uniaxial | | | | | | | (Positive B plate) |
| Example 6 | Resin D | 193 | Simultaneous | 132 | 1.4 × 1.4 | 138 | 89 | 1.45 | −1079 | nx = ny < nz |
| | | | biaxial | | | | | | | (Positive C plate) |
| Comparative | Resin E | 248 | Free-end | 165 | 2 | 184 | 705 | 1.17 | −352 | nx = nz > ny |
| Example 1 | | | uniaxial | | | | | | | (Negative A plate) |

TABLE 2

| | | Undrawn film | | | | | | | | |
|---|---|---|---|---|---|---|---|---|---|---|
| | Base | | | Coating | Drawing conditions | | | Film after drawing | | |
| | material | Starting | Total | layer | | Drawing | | Total | R₀ (550 | |
| | layer | material | thickness | thickness | Drawing | temperature | Draw | thickness | nm) | R₀ (450 nm)/ |
| | resin | resin | [μm] | [μm] | method | [° C.] | ratio | [μm] | [nm] | R₀ (550 nm) |
| Example 7 | PA | Resin A | 38 | 8 | Fixed-end | 137 | 2.5 | 15 | 127 | 0.82 |
| | | | | | uniaxial | | | | | |
| Example 8 | PA | Resin B | 38 | 4 | Free-end | 160 | 1.5 | 31 | 124 | 0.86 |
| | | | | | uniaxial | | | | | |
| Example 9 | PA | Resin D | 50 | 18 | Fixed-end | 137 | 2.5 | 20 | 169 | 0.81 |
| | | | | | uniaxial | | | | | |
| Example 10 | PC | Resin B | 63 | 38 | Free-end | 167 | 2 | 47 | 139 | 0.87 |
| | | | | | uniaxial | | | | | |
| Comparative | PA | Resin E | 32 | 3 | Free-end | 140 | 1.5 | 22 | 182 | 1.02 |
| Example 2 | | | | | uniaxial | | | | | |
| Comparative | PA | Uncoated | 26 | 0 | Free-end | 140 | 1.5 | 24 | 272 | 1.02 |
| Example 3 | | | | | uniaxial | | | | | |

As is evident from Table 1, the polyester resin of the present invention was confirmed to have a very high phase difference value and wavelength dispersibility as compared with a conventional polyester resin having a fluorene ring in a side chain. All the materials had a negative value of phase difference Rth in a thickness direction, demonstrating that these materials can be used as a negative A plate, a positive B plate, and a positive C plate for viewing angle compensation of a display apparatus.

As is evident from Table 2, a phase difference film that exhibited reverse dispersibility as wavelength dispersion of a phase difference was able to be formed by the lamination of a layer comprising the polyester resin of the present invention and a film having a positive phase difference. Such a phase difference film was confirmed to be capable of more thinning a conventionally known ¼λ phase difference film subjected to orientation treatment by drawing.

### INDUSTRIAL APPLICABILITY

The phase difference film of the present invention has a negative value of phase difference Rth in a thickness direction, is a thin film, produces a sufficient phase difference, is not fragile, and is easy to handle, and as such, can be used as a suitable negative A plate, positive B plate, or positive C plate. Furthermore, a laminated film thereof with a resin layer having positive intrinsic birefringence can be prepared as a thin ¼λ phase difference film that exhibits reverse dispersibility as wavelength dispersion of a phase difference. Such a phase difference film can have a viewing angle compensation function by lamination with a polarizing plate and is suitably used in an image display apparatus (e.g., a reflective liquid crystal display apparatus, a semi-transmissive liquid crystal display apparatus, and an organic EL display apparatus) having the polarizing plate.

### REFERENCE SIGNS LIST

10 . . . phase difference film, 11 . . . polyester resin layer, 12 . . . resin layer having positive intrinsic birefringence, 20 and 30 . . . polarizing plate, 21, 23, 31, 33, and 35 . . . adhesive layer, 22 and 34 . . . polarizer, 24, 32, and 36 . . . polarizer protective film, 40 . . . organic EL display apparatus, 41 . . . organic EL display panel, 42 . . . touch sensor, 43 . . . front panel, 50 . . . liquid crystal display apparatus, 51 . . . light source, 52 . . . liquid crystal panel, 53 . . . front panel, 60 . . . information processing apparatus, 61 . . . image display apparatus, 62 . . . image display apparatus housing.

1. A phase difference film comprising
one layer or multiple layers, wherein
at least one layer thereof comprises a composition containing a polyester resin having arylated fluorene in a side chain,
a relationship between phase differences Ro(450) and Ro(550) in an in-plane direction of the layer comprising the polyester resin is Ro(450)/Ro(550)≥1.22, and
the layer(s) is drawn.

2. The phase difference film according to claim 1, wherein
the composition exhibits negative intrinsic birefringence.

3. The phase difference film according to claim 1, wherein
the polyester resin comprises, as monomers, a dicarboxylic acid component represented by the following general formula (1) and at least one diol component selected from the group consisting of a diol component (A) represented by the following general formula (2), a diol component (B) represented by the following general formula (3), and a diol component (C) represented by the following general formula (4), and
in the contained polyester resin, k is 1 or more in at least a portion or the whole of the dicarboxylic acid component represented by the following general formula (1): 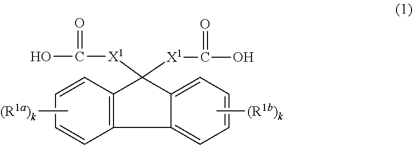
wherein R^{1a} and R^{1b} each independently represent a phenyl group or a naphthyl group, each k independently represents an integer of 0 to 4, and each X¹ independently represents a C₁₋₈ alkylene group, 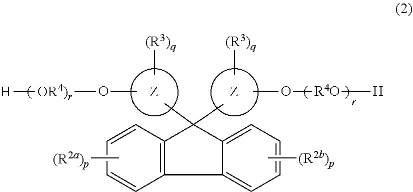
wherein each Z independently represents a phenylene group or a naphthylene group, R^{2a} and R^{2b} each independently represent a substituent inert to reaction, each p independently represents an integer of 0 to 4, each R³ independently represents an alkyl group, an alkoxy group, a cycloalkyloxy group, an aryloxy group, an aralkyloxy group, an aryl group, a cycloalkyl group, an aralkyl group, a halogen atom, a nitro group, or a cyano group, each q independently represents an integer of 0 to 2, each R⁴ independently represents a C₂₋₆ alkylene group, and each r independently represents an integer of 1 or larger, 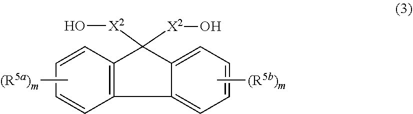
wherein R^{5a} and R^{5b} each independently represent a substituent inert to reaction, each m independently represents an integer of 0 to 4, and each X² independently represents a C₁₋₈ alkylene group,
HO—X³—OH (4)
wherein X³ represents a C₂₋₈ alkylene group.

4. The phase difference film according to claim 3, wherein
the polyester resin comprises a polyester resin comprising, as monomers, a dicarboxylic acid component of the general formula (1) wherein each of R^{1a} and R^{1b} is a 2-naphthyl group, k is 1, and X¹ is an ethylene group, and at least one diol component selected from the group consisting of a diol component (A) of the general formula (2) wherein Z is a phenylene group, each of p and q is 0, R⁴ is an ethylene group, and r is 1, and a diol component (C) of the general formula (4) wherein X³ is an ethylene group.

5. The phase difference film according to claim 1, wherein
the composition containing the polyester resin having the arylated fluorene in a side chain is a polymer alloy comprising the polyester resin having the arylated fluorene in a side chain, and a polycarbonate resin.

6. The phase difference film according to claim 1, wherein the phase difference film is a multilayer film comprising a layer comprising the polyester resin, and a resin layer having positive intrinsic birefringence.

7. The phase difference film according to claim 6, wherein
the resin layer having positive intrinsic birefringence comprises a polyamide-based resin.

8. The phase difference film according to claim 1, wherein
the phase difference film is a ¼λ phase difference film.

9. The phase difference film according to claim 1, wherein
when an in-plane direction of the phase difference film that exhibits a maximum refractive index is defined as an X axis, an in-plane direction of the phase difference film that is orthogonal to the X axis is defined as a Y axis, and a thickness direction of the phase difference film is defined as a Z axis,
a refractive index (nx) of the X axis, a refractive index (ny) of the Y axis, and a refractive index (nz) of the Z axis satisfy any of relationships represented by the following expressions (5) to (7):
nx=nz>ny (5)
nz>nx>ny (6)
nx=ny<nz (7)

10. The phase difference film according to claim 1, wherein
the phase difference film is a multilayer film comprising a liquid crystal phase difference layer made of an oriented liquid crystal material.

11. The phase difference film according to claim 1, wherein
the phase difference film is a multilayer film having a transparent conductive layer on one side or both sides.

12. The phase difference film according to claim 11, wherein
the transparent conductive layer comprises a plurality of metal thin wires.

13. The phase difference film according to claim 12, wherein
the metal thin wires are made of silver, copper, or an alloy comprising at least one of silver and copper.

14. The phase difference film according to claim 1, wherein
the transparent conductive layer comprises at least one of indium tin oxide (ITO), antimony-doped tin oxide (ATO), a conductive polymer, and a carbon-based material.

15. A method for producing the phase difference film according to claim 1, comprising
a drawing step of drawing a film comprising one layer or multiple layers comprising a composition containing a polyester resin having arylated fluorene in a side chain in a direction of 45°±15° with respect to a width direction.

16. A method for producing a film comprising multiple layers as the phase difference film according to claim 1, comprising the steps of:
performing multilayer film formation of the film comprising multiple layers by a coextrusion molding method, a coating molding method, an extrusion lamination molding method, or a lamination method; and
then drawing the film.

17. A polarizing plate comprising
the phase difference film according to claim 1.

18. The polarizing plate according to claim 17, further comprising
a ¼λ phase difference film on the visible side of the phase difference film.

19. The polarizing plate according to claim 18, wherein
the polarizing plate has a surface treatment layer on the ¼λ phase difference film on the visible side.

20. The polarizing plate according to claim 19, wherein
the surface treatment layer has any one or more of hard coat, antiglare, antireflection, low-reflection, antifouling, and anti-fingerprint effects.

21. An image display apparatus comprising
the polarizing plate according to claim 17.

22. The image display apparatus according to claim 21, further comprising a touch sensor.

23. The image display apparatus according to claim 22, wherein
the touch sensor has an on-cell system or an in-cell system.

24. The image display apparatus according to claim 22, wherein
the touch sensor is a capacitive touch sensor having at least one conductive film.

25. The image display apparatus according to claim 24, wherein
a base material of the conductive film is a polyester resin, a cycloolefin resin, a polycarbonate resin, or a polyimide resin.

26. The image display apparatus according to claim 24, wherein
the conductive film comprises a plurality of metal thin wires.

27. The image display apparatus according to claim 26, wherein
the metal thin wires are made of silver, copper, or an alloy comprising at least one of silver and copper.

28. The image display apparatus according to claim 24, wherein
the conductive film comprises at least one of indium tin oxide (ITO), antimony-doped tin oxide (ATO), a conductive polymer, and a carbon-based material.

29. The image display apparatus according to claim 21, wherein
the image display apparatus has a changeable shape.

30. The image display apparatus according to claim 21, wherein
the image display apparatus is an in-car image display apparatus.

31. An information processing apparatus comprising
the image display apparatus according to claim 21.
